(19) United States
(12) Patent Application Publication
(10) Pub. No.: US 2023/0317904 A1
(43) Pub. Date: Oct. 5, 2023

(54) FLEXIBLE ELECTRONIC DEVICE AND MANUFACTURING METHOD THEREOF

(71) Applicant: InnoLux Corporation, Miao-Li County (TW)

(72) Inventors: Yuan-Lin WU, Miao-Li County (TW); Tsung-Han TSAI, Miao-Li County (TW); Kuan-Feng LEE, Miao-Li County (TW); Cheng-Hsu CHOU, Miao-Li County (TW)

(73) Assignee: InnoLux Corporation, Miao-Li County (TW)

(21) Appl. No.: 18/108,674

(22) Filed: Feb. 13, 2023

(30) Foreign Application Priority Data
Mar. 30, 2022 (CN) 202210330701.6

(51) Int. Cl. H01L 33/62; H01L 33/00

(52) U.S. Cl. CPC H01L 33/62; H01L 33/005; H01L 2933/0066

(57) ABSTRACT

A manufacturing method of a flexible electronic device includes providing a carrier substrate, forming a first layer on the carrier substrate, forming an insulating layer on a first surface of the first layer, forming a plurality of transistors on the insulating layer, wherein the plurality of transistors include at least one first transistor and at least one second transistor, patterning the insulating layer into a plurality of first portions, wherein the at least one first transistor and the at least one second transistor are respectively disposed on two adjacent ones of the plurality of first portions, removing the carrier substrate, and attaching a flexible substrate to a second surface of the first layer opposite to the first surface. The two adjacent ones of the plurality of first portions are isolated from each other.

### BACKGROUND OF THE DISCLOSURE

### 1. Field of the Disclosure

The present disclosure relates to a flexible electronic device and a manufacturing method thereof, and more particularly to a stretchable electronic device and a manufacturing method thereof.

### 2. Description of the Prior Art

The flexible electronic device can be fixed to a curved surface by stretching and/or bending the electronic device. For example, the flexible electronic device can be attached to curved surfaces such as skin, car panel, curved glass, and the like. Therefore, the flexible electronic device can for example serve as biosensors, electronic elements in car or can be used in other suitable purposes. As demands of users for flexible electronic devices become higher, to improve the reliability of flexible electronic device is still an important issue in the related field.

### SUMMARY OF THE DISCLOSURE

In some embodiments, a manufacturing method of a flexible electronic device is provided by the present disclosure. The manufacturing method of the flexible electronic device includes providing a carrier substrate, forming a first layer on the carrier substrate, forming an insulating layer on a first surface of the first layer, forming a plurality of transistors on the insulating layer, wherein the plurality of transistors include at least one first transistor and at least one second transistor, patterning the insulating layer into a plurality of first portions, wherein the at least one first transistor and the at least one second transistor are respectively disposed on two adjacent ones of the plurality of first portions, removing the carrier substrate, and attaching a flexible substrate to a second surface of the first layer opposite to the first surface. The two adjacent ones of the plurality of first portions are isolated from each other.

In some embodiments, a flexible electronic device is provided by the present disclosure. The flexible electronic device includes a flexible substrate, an insulating layer disposed on the flexible substrate and including a plurality of first portions, and a plurality of transistors disposed on the insulating layer and including at least one first transistor and at least one second transistor, wherein the at least one first transistor and the at least one second transistor are respectively disposed on two adjacent ones of the plurality of first portions. The two adjacent ones of the plurality of first portions are isolated from each other.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a top view of an electronic device according to a first embodiment of the present disclosure.

FIG. 2A schematically illustrates a partial top view of an electronic device according to a variant embodiment of the first embodiment of the present disclosure.

FIG. 2B schematically illustrates a top view of an electronic device according to a second embodiment of the present disclosure.

FIG. 2C schematically illustrates a top view of an electronic device according to a third embodiment of the present disclosure.

FIG. 2D schematically illustrates a top view of an electronic device according to a variant embodiment of the third embodiment of the present disclosure.

FIG. 3A schematically illustrates a partial-enlarged top view of the electronic device according to the first embodiment of the present disclosure.

FIG. 3B schematically illustrates a cross-sectional view of the electronic device according to the first embodiment of the present disclosure along a section line A-A′.

FIG. 4A shows a flow chart of a manufacturing process of the electronic device according to the second embodiment of the present disclosure.

FIG. 4B, FIG. 4C, FIG. 4D, FIG. 4E and FIG. 4F schematically illustrate top views of the manufacturing process of the electronic device according to the second embodiment of the present disclosure.

FIG. 5A, FIG. 5B, FIG. 5C, FIG. 5D, FIG. 5E and FIG. 5F schematically illustrate cross-sectional views of the manufacturing process of the electronic device according to the second embodiment of the present disclosure.

FIG. 6A, FIG. 6B and FIG. 6C schematically illustrate cross-sectional views of a manufacturing process of an electronic device according to a variant embodiment of the second embodiment of the present disclosure.

FIG. 7A, FIG. 7B and FIG. 7C schematically illustrate cross-sectional views of a manufacturing process of an electronic device according to another variant embodiment of the second embodiment of the present disclosure.

FIG. 8A, FIG. 8B and FIG. 8C schematically illustrate top views of the manufacturing process of the electronic device according to the first embodiment of the present disclosure.

FIG. 9A, FIG. 9B, FIG. 9C and FIG. 9D schematically illustrate cross-sectional views of the manufacturing process of the electronic device according to the first embodiment of the present disclosure.

FIG. 10A, FIG. 10B and FIG. 10C schematically illustrate cross-sectional views of a manufacturing process of an electronic device according to a variant embodiment of the first embodiment of the present disclosure.

FIG. 11A and FIG. 11B schematically illustrate cross-sectional views of a manufacturing process of an electronic device according to another variant embodiment of the first embodiment of the present disclosure.

FIG. 11C schematically illustrates a cross-sectional view of an electronic device according to yet another variant embodiment of the first embodiment of the present disclosure.

FIG. 11D schematically illustrates a method for measuring a roughness of a first layer.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to...”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “coupled” to another element or layer, it can be a direct electrical connection or an indirect electrical connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

In addition, any two values or directions used for comparison may have certain errors. In addition, the terms “equal to”, “equal”, “the same”, “approximately” or “substantially” are generally interpreted as being within ± 10%, ± 5%, ± 3%, ± 2%, ± 1%, or ± 0.5% of the given value.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

The electronic device of the present disclosure may include a display device, a sensing device, a back-light device, an antenna device, a tiled device or other suitable electronic devices, but not limited thereto. The electronic device may be a foldable electronic device, a flexible electronic device or a stretchable electronic device. For example, the electronic device of the present disclosure may include a flexible electronic device. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may for example include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. In addition, the outline of the electronic device may be a rectangle, a circle, a polygon, a shape with curved edge or other suitable shapes. The electronic device may include electronic elements, wherein the electronic elements may include passive elements or active elements, such as capacitor, resistor, inductor, diode, transistor, sensors, and the like. The diode may include a light emitting diode or a photo diode. The light emitting diode may for example include an organic light emitting diode (OLED) or an in-organic light emitting diode. The in-organic light emitting diode may for example include a mini light emitting diode (mini LED), a micro light emitting diode (micro LED) or a quantum dot light emitting diode (QLED), but not limited thereto. The electronic device may include peripheral systems such as driving systems, control systems, light source systems, shelf systems, and the like for supporting the display device, the antenna device or the tiled device. It should be noted that the electronic device of the present disclosure may be combinations of the above-mentioned devices, but not limited thereto. The display device is taking as an example to describe the contents of the present disclosure in the following, but the present disclosure is not limited thereto.

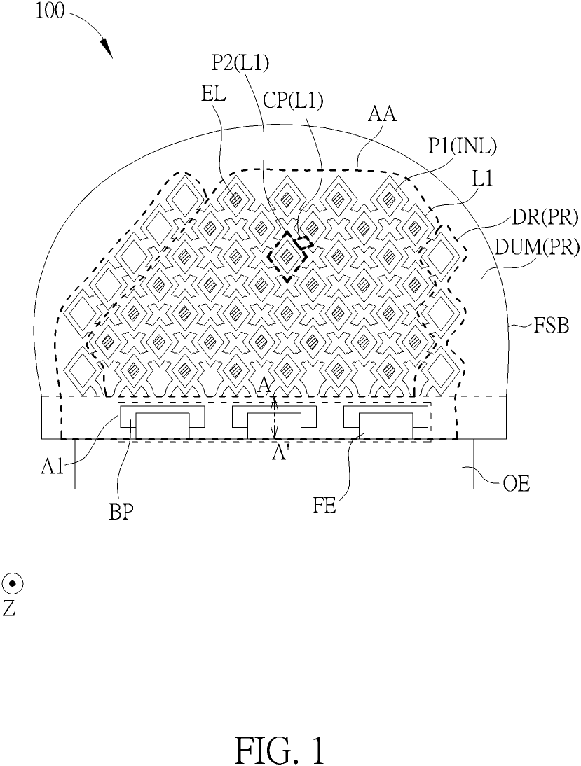

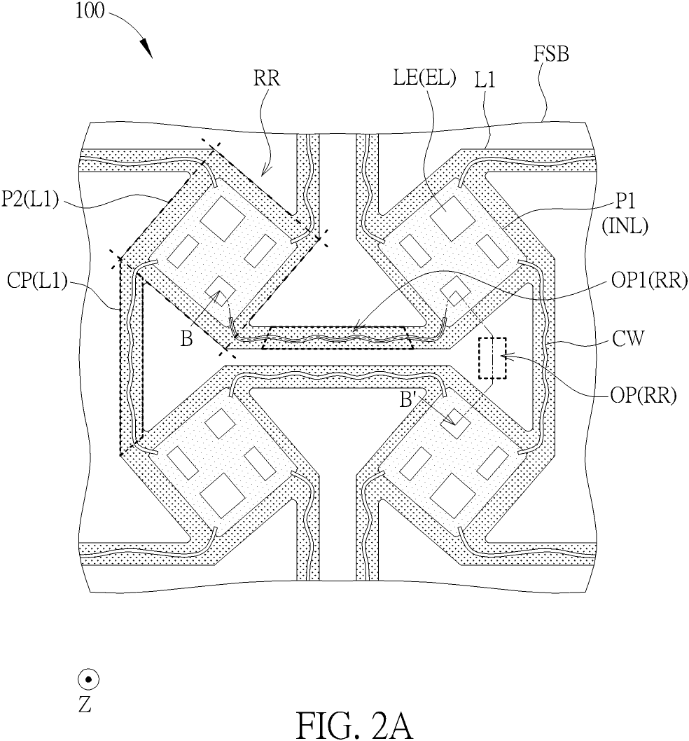

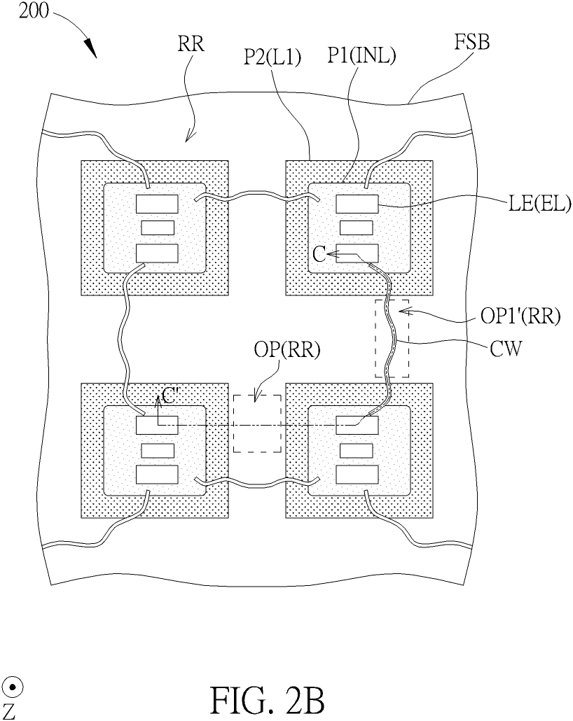

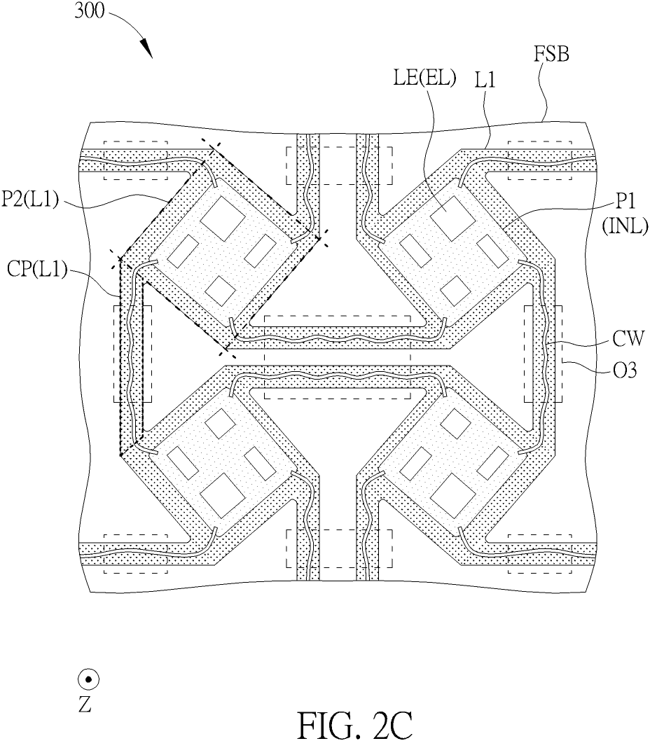

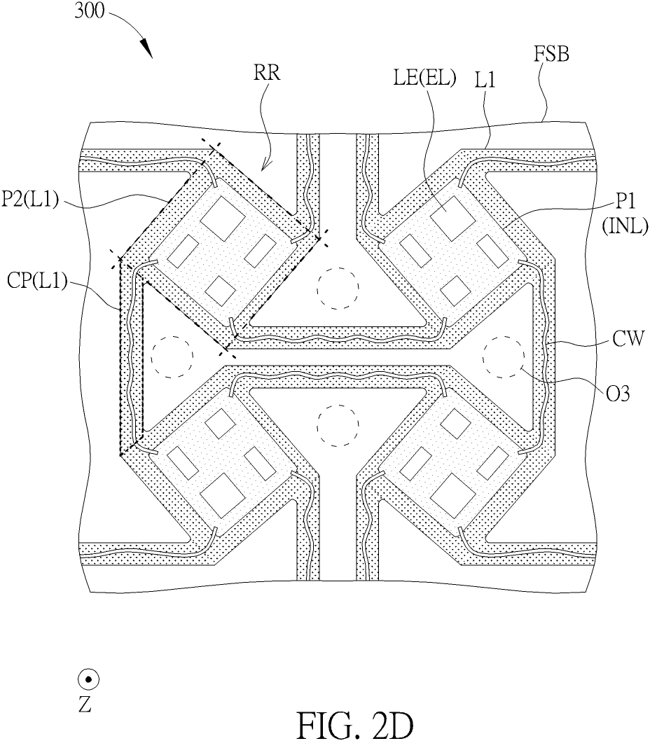

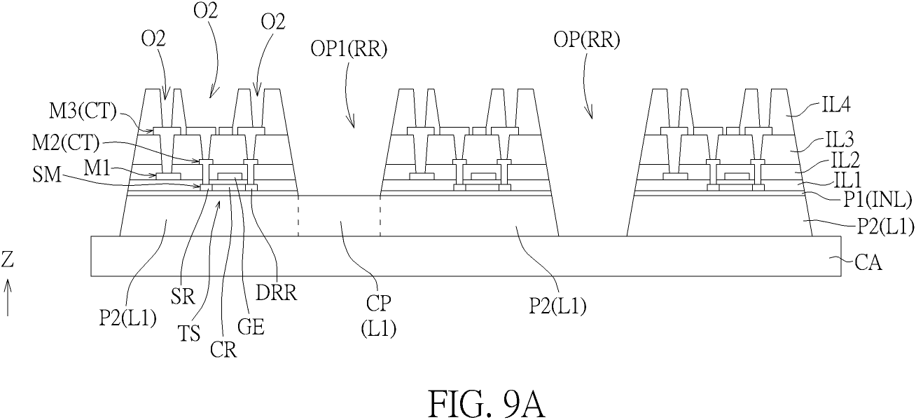

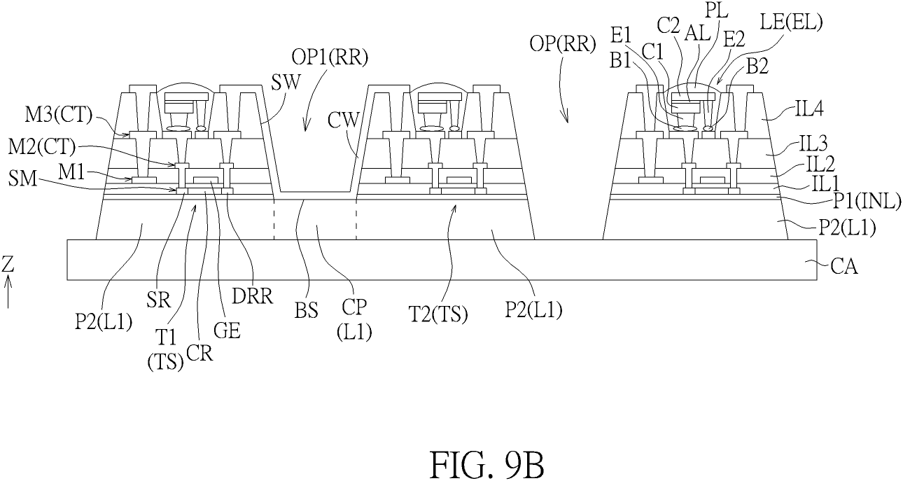

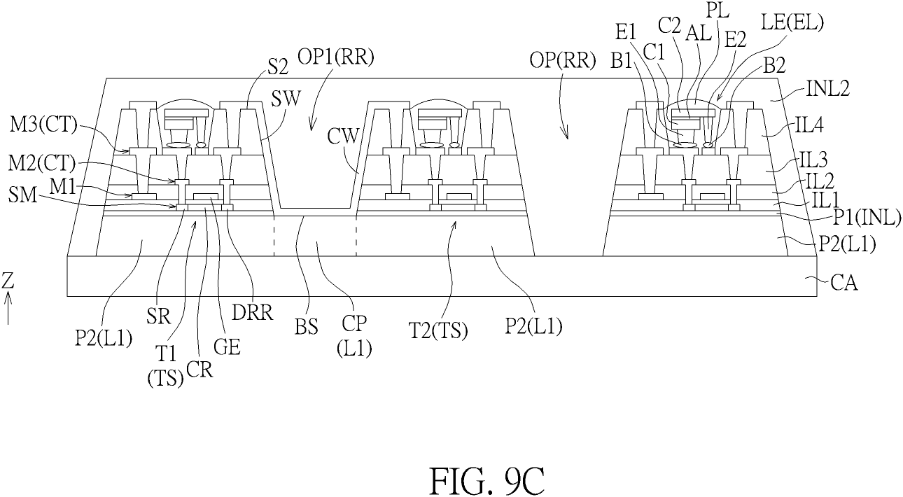

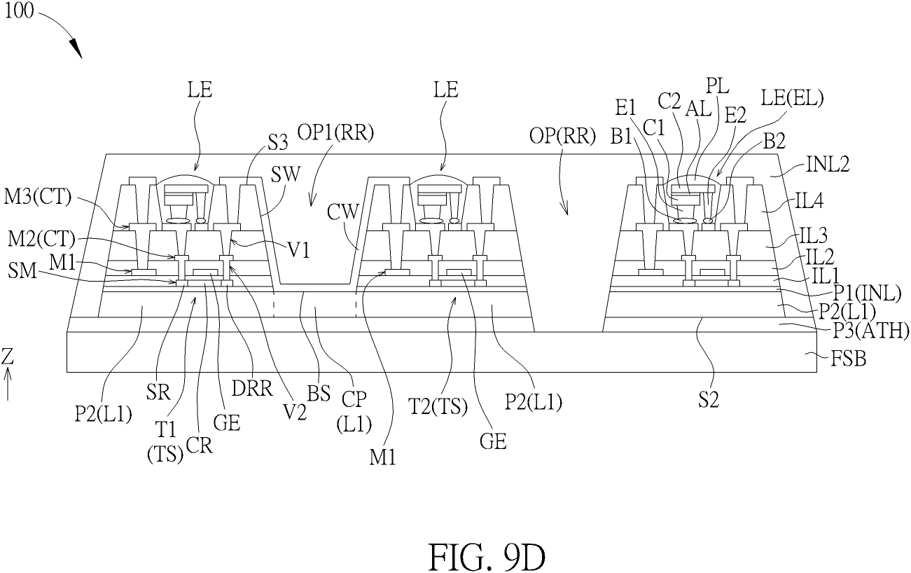

Referring to FIG. 1, FIG. 2A and FIG. 9D, FIG. 1 schematically illustrates a top view of an electronic device according to a first embodiment of the present disclosure, FIG. 2A schematically illustrates a partial top view of an electronic device according to a variant embodiment of the first embodiment of the present disclosure, and FIG. 9D shows a cross-sectional structure of what is shown in FIG. 2A along a section line B-B′. According to the present embodiment, the electronic device 100 may include a flexible substrate FSB, a first layer L1, an insulating layer INL and electronic elements EL, wherein the first layer L1 may be disposed on the flexible substrate FSB, the insulating layer INL may be disposed on the first layer L1, and the electronic elements EL may be disposed on the insulating layer INL, but not limited thereto. As shown in FIG. 1, the electronic device 100 may include an active region AA and a peripheral region PR. The active region AA may be a region of the electronic device 100 including the electronic elements EL, and the active region AA may have various uses according to the type of the electronic elements EL. Specifically, the electronic elements EL may for example include display elements, sensing elements or other suitable elements, wherein when the electronic elements EL include display elements, the active region AA may be the display region of the electronic device 100; and when the electronic elements EL include sensing elements, the active region AA may be the sensing region of the electronic device 100, but not limited thereto. The range of the active region AA may for example be defined through the electronic elements EL. In detail, the active region AA may be defined as a region enclosed by the outer edge of the outermost electronic elements EL among the plurality of electronic elements EL. The peripheral region PR may the region of the electronic device 100 other than the active region AA. In the present embodiment, the peripheral region PR may include a driving region DR and a dummy region DUM, but not limited thereto. The driving region DR may include conductive wires, wires or other suitable electronic elements. In addition, the driving region DR may further include bonding pads BP, flexible electronic elements FE and an external electronic element OE, but not limited thereto. The signal lines (not shown) of the electronic elements EL may be pulled out to the driving region DR and coupled to the bonding pads BP, and the signal lines may be coupled to the external electronic element OE through the bonding pads BP and the flexible electronic elements FE, but not limited thereto. The flexible electronic elements FE may for example include a flexible printed circuit board (FPCB), and the external electronic elements OE may for example include printed circuit board, but not limited thereto. The dummy region DUM may be a region of the electronic device 100 that does not include the first layer L1, the insulating layer INL and/or other conductive elements (such as electronic elements, wires, and the like). For example, the dummy region DUM may include the flexible substrate FSB, but not limited thereto. It should be noted that the ranges of the active region AA and the peripheral region PR shown in FIG. 1 are just exemplary, which do not represent the actual ranges of the active region AA and the peripheral region PR. In addition, the shapes of the active region AA and the peripheral region PR of the electronic device 100 are not limited to what is shown in FIG. 1 and may be various according to the design of the product.

According to the present embodiment, the flexible substrate FSB may be curved, bent, rolled, stretched or deformed in any way. For example, the flexible substrate FSB may be a stretchable substrate, but not limited thereto. The flexible substrate FSB may be used to support the layers and/or the structures disposed thereon. The material of the flexible substrate FSB may include polyimide (PI), polycarbonate (PC), polyethylene terephthalate (PET), other suitable materials or combinations of the above-mentioned materials, but not limited thereto.

As shown in FIG. 1 and FIG. 2A, the insulating layer INL may be disposed on the flexible substrate FSB, wherein the insulating layer INL may include a plurality of first portions P1. According to the present embodiment, any two adjacent ones of the plurality of first portions P1 of the insulating layer INL may be isolated from each other in a top view direction (that is, the direction Z) of the electronic device 100. That is, a spacing is included between two adjacent ones of the plurality of first portions P1. In other words, in the top view direction of the electronic device 100, each of the first portions P1 of the insulating layer INL may be independent and is not connected to other first portions P1. The first portion P1 may include any suitable shape. In an embodiment, the first portion P1 may be rectangular, but not limited thereto. The above-mentioned “two first portions P1 are isolated from each other” may represent that the two first portions P1 are not connected to each other through an element including the material the same as the material of the insulating layer INL (or the first portion P1) in the top view direction of the electronic device 100. In other words, in the top view direction of the electronic device 100, the first portion P1 or the element including the material the same as the material of the first portion P1 are not included between two adjacent first portions P1. That is, other portions of the insulating layer INL are not disposed between two adjacent first portions P1. The insulating layer INL may include a single-layer structure or a multi-layer structure. In addition, the insulating layer INL may include any suitable organic material and/or inorganic material. The organic material may for example include acrylic resin, epoxy resin, siloxane, silicon, other suitable materials or combinations of the above-mentioned materials. The inorganic material may include silicon nitride, silicon oxide, liquid glass, glass glue, titanium dioxide, aluminum oxide, other suitable materials or combinations of the above-mentioned materials. When the insulating layer INL includes the single-layer structure, the insulating layer INL may for example include inorganic materials; and when the insulating layer INL includes the multi-layer structure, the insulating layer INL may for example include a stacked structure formed of inorganic material/organic material/inorganic material, but not limited thereto. According to the present embodiment, the insulating layer INL may for example serve as the buffer layer of the electronic device 100 to block moisture and/or oxygen from outside, thereby reducing the possibility that the elements in the electronic device 100 are damaged due to the effect of moisture and/or oxygen.

As shown in FIG. 9D, the first layer L1 may be disposed between the flexible substrate FSB and the insulating layer INL. The first layer L1 may for example include the flexible substrate or at least partially be the flexible substrate. For example, the first layer L1 may be a stretchable substrate, but not limited thereto. The material of the first layer L1 may refer to the material of the flexible substrate FSB mentioned above, and will not be redundantly described. In an embodiment, the material of the first layer L1 and the material of the flexible substrate FSB may be the same. In another embodiment, the material of the first layer L1 and the material of the flexible substrate FSB may be different, but not limited thereto. According to the present embodiment, the first layer L1 may include a plurality of second portions P2 and a plurality of connecting portions CP, wherein at least one of the plurality of connecting portions CP may connect two adjacent ones of the plurality of second portions P2. Specifically, as shown in FIG. 1 and FIG. 2A, a second portion P2 of the first layer L1 may be connected to at least one connecting portion CP, and the second portion P2 may be connected to another second portion P2 through the at least one connecting portion CP to which the second portion P2 is connected. It should be noted that although FIG. 1 and FIG. 2A show the first layers with different patterns, the pattern of the first layer L1 of the present embodiment is not limited thereto. According to the present embodiment, the region of the second portion P2 may for example be defined through extending lines passing through the edges of the second portion P2. Taking the first layer L1 shown in FIG. 2A as an example, the region enclosed by the extending lines of the four edges of the second portion P2 of the first layer L1 may for example be defined as the region of the second portion P2, but not limited thereto. After the second portions P2 are defined, the portions in the first layer L1 other than the second portions P2 may be defined as the connecting portions CP, but not limited thereto. As shown in FIG. 1 and FIG. 2A, the shape of the second portion P2 may for example be a rectangle, and the shape of the connecting portion CP may for example be a trapezoid, but not limited thereto. In some embodiments, the shape of the second portion P2 may be a circle, a polygon, a curved edge or other suitable shapes.

According to the present embodiment, at least one of the plurality of first portions P1 of the insulating layer INL may be disposed on at least one of the plurality of second portions P2 of the first layer L1. In other words, at least one of the first portions P1 may be disposed corresponding to a second portion P2. The “at least one of the first portions P1 is disposed corresponding to a second portion P2” described herein may represent that the at least one of the first portions P1 is overlapped with or at least partially overlapped with the second portion P2 in the top view direction (the direction Z) of the electronic device 100, but not limited thereto. The definition of the term “corresponding to” mentioned above may be applied to each of the embodiments of the present disclosure, and will not be redundantly described. For example, as shown in FIG. 1 and FIG. 2A, a first portion P1 may correspond to a second portion P2 and disposed on the second portion P2, but not limited thereto. In some embodiments, a second portion P2 may correspond to multiple first portions P1. In some embodiments, some of the first portions P1 may not correspond to some of the second portions P2.

As shown in FIG. 9D, the electronic device 100 may further include an attaching layer ATH, wherein the attaching layer ATH may be disposed between the first layer L1 and the flexible substrate FSB. In detail, the attaching layer ATH may be used to attach the flexible substrate FSB to the first layer L1. For example, the flexible substrate FSB may be fixed to the first layer L1 through attachment or adhesion, but not limited thereto. The attaching layer ATH may include any suitable adhesive material.

As shown in FIG. 9D, the electronic device 100 may further include a plurality of transistors TS, wherein the transistors TS may be disposed on the insulating layer INL. In other words, the transistors TS may be disposed on the first portions P1. The transistors TS may for example include thin film transistors (TFTs), but not limited thereto. In detail, the electronic device 100 may include a semiconductor SM disposed on the insulating layer INL and a metal layer M1 disposed on the semiconductor SM. The transistor TS includes the semiconductor SM and a gate GE disposed on the semiconductor SM, wherein the metal layer M1 may include the gate GE of the transistor TS, and the semiconductor SM may include a channel region CR, a source region SR and a drain region DRR, but not limited thereto. The metal layer M1 may include any suitable conductive material. The material of the semiconductor SM may for example include silicon or metal oxides, such as low temperature polysilicon (LTPS) semiconductor, amorphous silicon (a-Si) semiconductor or indium gallium zinc oxide (IGZO) semiconductor, but not limited thereto. According to the present embodiment, at least one of the transistors TS may be disposed on a first portion P1 of the insulating layer INL, or a first portion P1 may correspond to at least one transistor TS. When the electronic device 100 includes a plurality of transistors TS, the semiconductors SM of different transistors TS may be the same or different. For example, the semiconductors SM of a portion of the transistors TS include silicon (such as low temperature polysilicon semiconductor) while the semiconductors SM of another portion of the transistors TS include metal oxides (such as indium gallium zinc oxide semiconductor). For example, as shown in FIG. 9D, the transistors TS may include at least one first transistor T1 and at least one second transistor T2, wherein the first transistor T1 and the second transistor T2 may respectively be disposed on two adjacent ones of the first portions P1, but not limited thereto. In some embodiments, multiple transistors TS may be disposed on a first portion P1. In addition, as shown in FIG. 9D, the electronic device 100 may further include an insulating layer IL1 disposed between the metal layer M1 and the semiconductor SM, an insulating layer IL2 disposed on the insulating layer IL1, an insulating layer IL3 disposed on the insulating layer IL2 and an insulating layer IL4 disposed on the insulating layer IL3, wherein the materials of the insulating layer IL1, the insulating layer IL2, the insulating layer IL3 and the insulating layer IL4 may refer to the material of the insulating layer INL mentioned above, and the materials of the insulating layers may be the same or different.

According to the present embodiment, the second portions P2 and the connecting portions CP of the first layer L1 and the first portions P1 of the insulating layer INL may for example be formed through a patterning process. The patterning process may include removing a portion of the insulating layer INL, a portion of the insulating layers (including the insulating layer IL1, the insulating layer IL2, the insulating layer IL3 and the insulating layer IL4) and a portion of the first layer L1. Therefore, after the patterning process, at least one recess region RR may be formed in the electronic device 100, as shown in FIG. 2A. The recess region RR may be defined as the region of the removed portions of the layers in the patterning process for forming the second portions P2 and the connecting portions CP of the first layer L1 and the first portions P1 of the insulating layer INL, and a portion of the flexible substrate FSB and/or a portion of the connecting portions CP may be exposed in the recess region RR. In the present embodiment, since the first layer L1 may include the connecting portions CP, the recess region RR may include an area corresponding to the connecting portions CP and another area not corresponding to the connecting portion CP. In the recess region RR, the depth of the area corresponding to the connecting portions CP and the depth of the another area not corresponding to the connecting portion CP may be different. For example, as shown in FIG. 2A and FIG. 9D, the recess region RR may include a first area OP1 corresponding to the connecting portion CP and a second area OP not corresponding to the connecting portion CP, wherein the portion of the first layer L1 corresponding to the first area OP1 may not be removed, the first area OP1 may expose the connecting portion CP of the first layer L1, the portion of the first layer L1 corresponding to the second area OP may be removed, and the second area OP may expose the flexible substrate FSB, but not limited thereto. Accordingly, the depth of the first area OP1 may be lower than the depth of the second area OP (the difference of the depths may substantially be the thickness of the connecting portion CP). It should be noted that FIG. 2A and FIG. 9D just exemplarily show a second area OP and a first area OP1, and the recess region RR may include multiple second areas OP not corresponding to the connecting portion CP and multiple first areas OP1 corresponding to the connecting portions CP.

The electronic device 100 may further include at least one conductive wire CW, wherein the conductive wire CW may be disposed on and extend on the connecting portions CP. For example, as shown in FIG. 2A, in the top view direction (the direction Z) of the electronic device 100, the conductive wire CW may extend from a first portion P1 (or second portion P2) to another first portion P1 (or second portion P2) along the connecting portion CP, but not limited thereto. As mentioned above, since the connecting portion CP may correspond to the first area OP1 of the recess region RR, the conductive wire CW disposed on the connecting portion CP may extend into the first area OP1. Specifically, at least a portion of the conductive wire CW may be disposed on the sidewall SW and the bottom surface BS of the first area OP1 or extend along the sidewall SW and the bottom surface BS of the first area OP1, such that the conductive wire CW can extend on the connecting portion CP and across the connecting portion CP to couple the electronic elements on the first portions P1 respectively at two sides of the connecting portion CP. In another aspect, the second area OP does not expose the connecting portion CP, and the conductive wire CW may not be disposed corresponding to the second area OP. The sidewall SW of the first area OP1 may include the side surfaces of the first portion P1, the insulating layer IL1, the insulating layer IL2, the insulating layer IL3 and the insulating layer IL4, and the bottom surface BS of the first area OP1 may be the upper surface of the connecting portion CP, but not limited thereto. Since the bottom of the first area OP1 is the exposed connecting portion CP, the conductive wire CW may contact the connecting portion CP. Specifically, the portion of the conductive wire CW disposed on the bottom surface BS of the first area OP1 may directly contact the connecting portion CP, but not limited thereto. According to the present embodiment, the conductive wire CW may be coupled to the transistors TS respectively on two adjacent ones of the first portions P1, such that these transistors TS may be coupled to each other through the conductive wire CW. In detail, as shown in FIG. 9D, in addition to the sidewall SW and the bottom surface BS of the first area OP1, a portion of the conductive wire CW may extend on the upper surface of the insulating layer IL4, the portion of the conductive wire CW may penetrate through the insulating layer IL4 and be coupled to contact elements CT, and the portion of the conductive wire CW may be coupled to the first transistor T1 and the second transistor T2 respectively on two adjacent first portions P1 through the contact elements CT. For example, the conductive wire CW may be coupled to the drain region DRR of the first transistor T1 through the contact element CT and to the gate GE of the second transistor T2 through the metal layer M1, but not limited thereto. In the present disclosure, the conductive wire CW may be coupled to the first transistor T1 and the second transistor T2, but the coupling way is not limited. Accordingly, the first transistor T1 and the second transistor T2 respectively on two adjacent first portions P1 may be coupled to each other through the conductive wire CW. That is, electrical signals may be transmitted between the transistors TS on different first portions P1 through the conductive wires CW, but not limited thereto. In addition, since a portion of the conductive wire CW may extend on the upper surface of the insulating layer IL4, a portion of the conductive wire CW may overlap the insulating layer INL in the top view direction of the electronic device 100, but not limited thereto. The conductive wire CW may include any suitable conductive material, such as metal materials, but not limited thereto.

As mentioned above, the electronic element EL may include a sensor, a diode or other suitable elements. In the following, the diode is taking as an example of the electronic element EL to describe the structure of the electronic element EL, but the present embodiment is not limited thereto. FIG. 2A and FIG. 9D show the structures in which the electronic elements EL includes diodes as light emitting units LE. As shown in FIG. 2A, the electronic elements EL may include light emitting units LE, wherein the light emitting units LE may be disposed on the first portions P1 and/or the second portions P2. In other words, the light emitting units LE may be disposed corresponding to the first portions P1 and/or the second portions P2. In the present embodiment, multiple light emitting units LE may be disposed on a first portion P1 (or second portion P2), wherein these light emitting units LE may emit lights of different colors that can be mixed into a required color, but not limited thereto. For example, the light emitting units LE on a first portion P1 (or second portion P2) may respectively emit red light, green light and blue light that can be mixed into a white light, but not limited thereto. In some embodiments, only one light emitting unit LE is disposed on a first portion P1 (or second portion P2). It should be noted that the arrangement of the light emitting units LE shown in FIG. 2A is exemplary, and the present embodiment is not limited thereto. For example, FIG. 9D shows the example that the light emitting units LE include in-organic light emitting diodes. As shown in FIG. 9D, the light emitting unit LE may include a semiconductor C1, a semiconductor C2, an active layer AL located between the semiconductor C1 and the semiconductor C2, an electrode E1 connected to the semiconductor C1 and an electrode E2 connected to the semiconductor C2, but not limited thereto. In addition, the electrode E1 and the electrode E2 of the light emitting unit LE may be coupled to the driving elements or other electronic elements in the electronic device 100 respectively through a bonding material B1 and a bonding material B2. For example, the light emitting units LE may be coupled to the transistors TS, and the light emission of the light emitting units LE may be driven through the transistors TS, but not limited thereto. Furthermore, the electronic device 100 of the present embodiment may further include a protecting layer PL, wherein the protecting layer PL may be disposed on the light emitting units LE and cover the light emitting units LE to provide protection, but not limited thereto.

According to the present embodiment, the electronic element EL may be disposed on one of the two adjacent first portions P1, and the electronic element EL may be coupled to the transistor TS on the first portion P1 where the electronic element EL is disposed. For example, the light emitting unit LE in the left part of FIG. 9D may be coupled to the first transistor T1, and the light emitting unit LE in the middle part of FIG. 9D may be coupled to the second transistor T2, but not limited thereto. It should be noted that the light emitting unit LE may be coupled to the transistor TS that is coupled to the conductive wire CW in a direct way or an indirect way. For example, the light emitting unit LE in the left part of FIG. 9D may be directly coupled to the first transistor T1 thorough a conductor, and the light emitting unit LE in the middle part of FIG. 9D may also be directly coupled to the second transistor T2 thorough a conductor, but not limited thereto. In some embodiments, multiple first transistors T1 (or second transistors T2) may be disposed on a first portion P1, and the light emitting unit LE and the conductive wire CW may be coupled to different first transistors T1 (or second transistors T2). In such situation, since the transistors TS on the same first portion P1 may be coupled to each other, the light emitting unit LE may still be coupled to the transistor TS that is coupled to the conductive wire CW. Accordingly, the electronic elements EL on different first portions P1 may be coupled to each other through the conductive wires CW.

Although it is not shown in FIG. 1, the electronic device 100 may further include an insulating layer INL2 in addition to the above-mentioned elements and/or layers, but not limited thereto. The insulating layer INL2 may contact the flexible substrate FSB and encapsulate the layers and the electronic elements (such as electronic elements EL, conductive wire CW, and the like) between the insulating layer INL2 and the flexible substrate FSB. The insulating layer INL2 may be filled into the areas (such as the second area OP and the first area OP1) of the recess region RR to provide protection. The material of the insulating layer INL2 may refer to the material of the insulating layer INL mentioned above, and will not be redundantly described.

According to the present embodiment, the insulating layer INL of the electronic device 100 may include a plurality of first portions P1 which are spaced apart from each other, wherein the first portions P1 may not be disposed corresponding to the connecting portions CP of the first layer L1. In other words, the portion of the insulating layer INL on the connecting portions CP may be removed. Accordingly, when the electronic device 100 is deformed (for example, being stretched), the stress on the connecting portions CP may be reduced, thereby reducing the possibility of breakage of the elements and/or the layers (such as the conductive wire CW) on the connecting portions CP. Therefore, the stretchability or reliability of the electronic device 100 may be improved. It should be noted that the structure of the electronic device 100 of the present embodiment is not limited to the above-mentioned contents, and other suitable elements and/or layers may be included in the electronic device 100 according to the demands of the design.

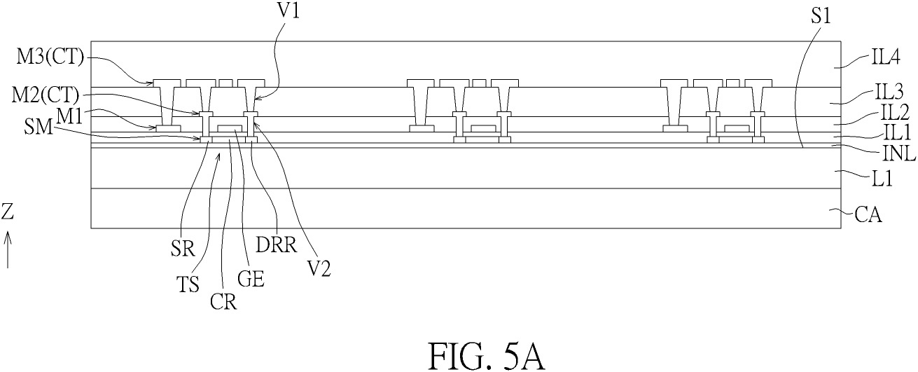

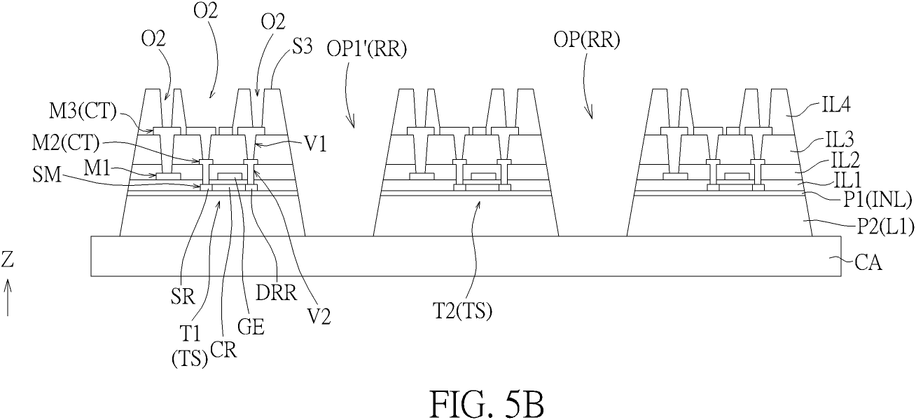

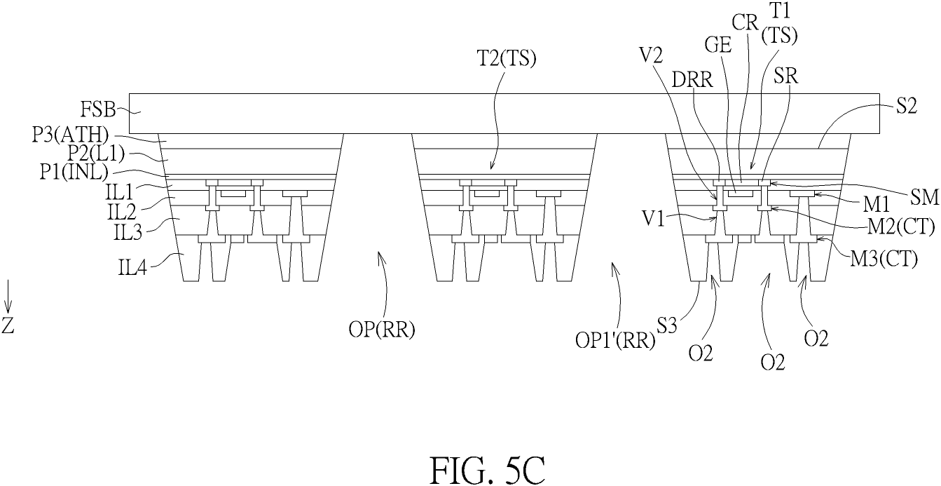

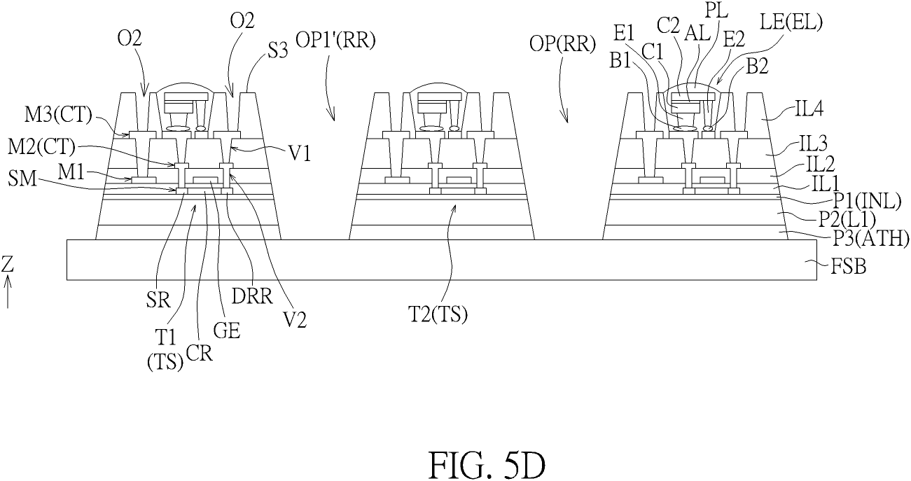

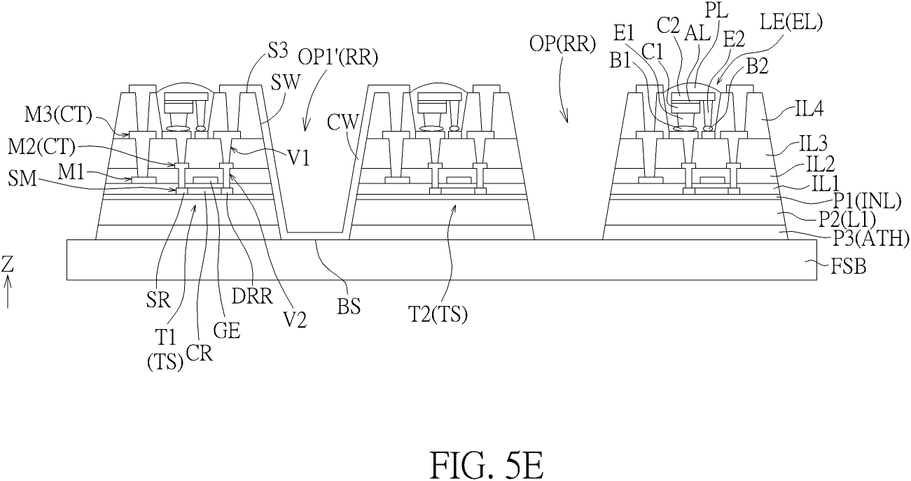

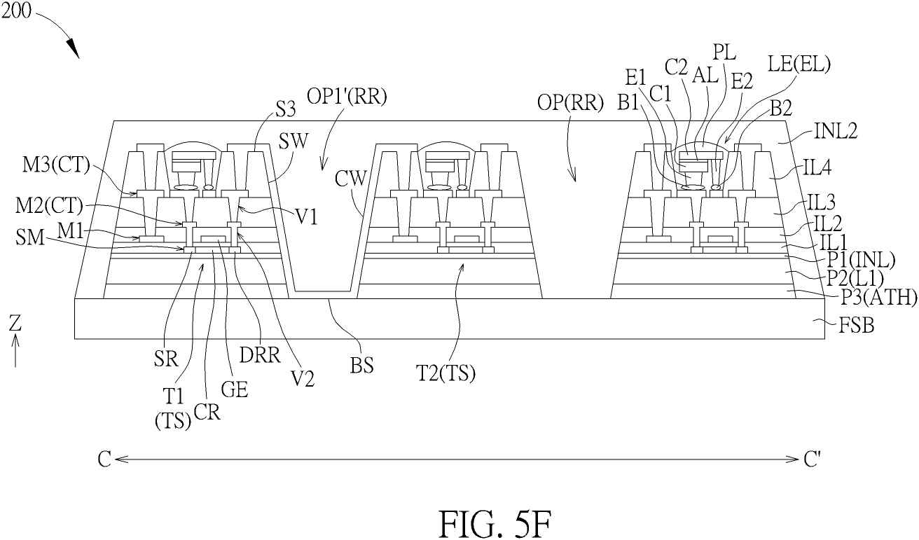

Referring to FIG. 2B and FIG. 5F, FIG. 2B schematically illustrates a top view of an electronic device according to a second embodiment of the present disclosure, and FIG. 5F shows the cross-sectional view of the structure in FIG. 2B along a section line C-C′. The electronic device 200 of the present embodiment may include the flexible substrate FSB, the first layer L1 disposed on the flexible substrate FSB, the insulating layer INL disposed on the first layer L1 and the electronic elements EL disposed on the insulating layer INL. The insulating layer INL may include the plurality of first portions P1, wherein the plurality of first portions P1 may be isolated from each other. The electronic elements EL of the present embodiment may include the light emitting units LE, but not limited thereto. In addition, compared with the light emitting units LE in FIG. 2A, the arrangement of the light emitting units LE in FIG. 2B is different, but the present embodiment is not limited thereto. According to the present embodiment, the first layer L1 disposed between the flexible substrate FSB and the insulating layer INL may include the plurality of second portions P2, wherein two adjacent ones of the plurality of second portions P2 may be isolated from each other in the top view direction (that is, the direction Z) of the electronic device 200. In other words, compared with the first layer L1 in the first embodiment, the first layer L1 in the present embodiment may include the second portions P2 but not include the connecting portion CP connecting the second portions P2. Accordingly, the second portions P2 may for example include any suitable shape, but not limited thereto. In addition, at least one of the plurality of first portions P1 may be disposed on one of the plurality of second portions P2. For example, a first portion P1 may be disposed on a second portion P2, but not limited thereto.

The electronic device 200 may further include a conductive wire CW, wherein the conductive wire CW may extend from a first portion P1 (or second portion P2) to another first portion P1 (or second portion P2) in the top view direction of the electronic device 200, and the conductive wire CW may be coupled to the transistors TS respectively on two adjacent first portions P1. As shown in FIG. 2B and FIG. 5F, the electronic device 200 may include a recess region RR, and the recess region RR may include a first area OP1′ and a second area OP, wherein the conductive wire CW may correspond to the first area OP1′ but not correspond to the second area OP, but not limited thereto. In other words, the conductive wire CW may be disposed corresponding to the first area OP1′. The related descriptions about the recess region RR and the areas thereof may refer to the above-mentioned contents, and will not be redundantly described. The conductive wire CW may be disposed on the sidewall SW and the bottom surface BS of the first area OP1′, or the conductive wire CW may extend along the sidewall SW and the bottom surface BS of the first area OP1′, such that the conductive wire CW may extend between different first portions P1 (or second portions P2). According to the present embodiment, since the electronic device 200 does not include the connecting portion CP, the first area OP1′ may expose the flexible substrate FSB. Therefore, the conductive wire CW may contact the flexible substrate FSB. Specifically, the portion of the conductive wire CW disposed on the bottom surface BS of the first area OP1′ may directly contact the flexible substrate FSB, but not limited thereto. In addition, a portion of the conductive wire CW may extend on the upper surface of the insulating layer IL4 and penetrate through the insulating layer IL4 to be coupled to the contact elements CT, and the portion of the conductive wire CW may be coupled to the first transistor T1 and the second transistor T2 respectively on two adjacent first portions P1 through the contact elements CT.

Furthermore, as shown in FIG. 5F, the electronic device 200 of the present embodiment may include the attaching layer ATH disposed between the first layer L1 and the flexible substrate FSB, wherein the attaching layer ATH may be used to attach or fix the flexible substrate FSB to the first layer L1. According to the present embodiment, the attaching layer ATH may include a plurality of third portions P3, wherein the plurality of third portions P3 may be disposed below the plurality of second portions P2 of the first layer L1. In other words, the third portions P3 may be disposed corresponding to the second portions P2, but not limited thereto. The details of other elements of the electronic device 200 of the present embodiment may refer to the electronic device 100 in the first embodiment, and will not be redundantly described.

Referring to FIG. 2C and FIG. 2D, FIG. 2C schematically illustrates a top view of an electronic device according to a third embodiment of the present disclosure, and FIG. 2D schematically illustrates a top view of an electronic device according to a variant embodiment of the third embodiment of the present disclosure. According to the present embodiment, the flexible substrate FSB of the electronic device 300 may include at least one opening 03. In other words, the flexible substrate FSB may be patterned. As shown in FIG. 2C, the openings 03 of the flexible substrate FSB may for example be disposed corresponding to the connecting portions CP of the first layer L1. That is, the openings 03 may overlap the conductive wires CW extending on the connecting portions CP in the top view direction of the electronic device 300. Accordingly, when the electronic device 300 is deformed (such as being stretched), the friction between the flexible substrate FSB and the first layer L1 and/or the conductive wires CW may be reduced, such that the possibility of breakage of the first layer L1 and/or the conductive wires CW may be reduced, thereby improving the reliability of the electronic device 300. It should be noted that the positions of the openings 03 are not limited to what is shown in FIG. 2C. In some embodiments, as shown in FIG. 2D, the openings 03 of the flexible substrate FSB may be formed corresponding to any suitable position where the first layer L1 is not included, but not limited thereto. Therefore, the stretchability of the flexible substrate FSB may be improved. In some embodiments, when the electronic device 300 does not include the connecting portion CP, the openings 03 of the flexible substrate FSB may for example be disposed corresponding to the conductive wires CW, but not limited thereto. The details of other elements of the electronic device 300 may refer to the electronic device 100 of the first embodiment, and will not be redundantly described.

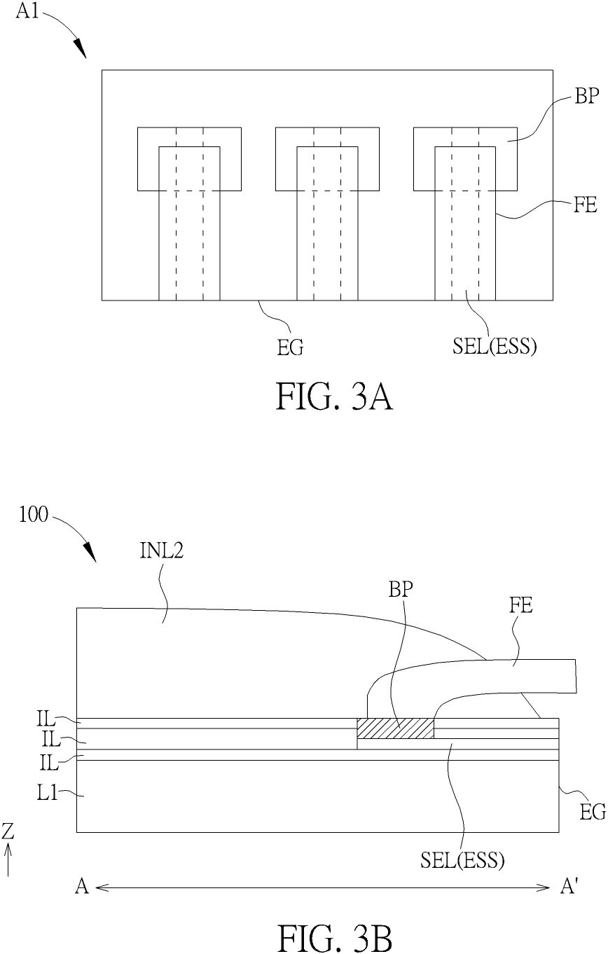

Referring to FIG. 3A and FIG. 3B, FIG. 3A schematically illustrates a partial-enlarged top view of the electronic device according to the first embodiment of the present disclosure, and FIG. 3B schematically illustrates a cross-sectional view of the electronic device according to the first embodiment of the present disclosure along a section line A-A′. Specifically, FIG. 3A shows a partial enlarged view of the portion A1 shown in FIG. 1. In addition, in order to simplify the figure, the stacked layers above the first layer L1 are exemplarily shown as a plurality of insulating layers IL in FIG. 3B, and the actual structure of the electronic device 100 is not limited thereto. Each of the insulating layers IL may for example be the insulating layer IL1, the insulating layer IL2, the insulating layer IL3 or the insulating layer IL4 shown in FIG. 9D, but not limited thereto. According to the present embodiment, the electronic device 100 may optionally include an electrostatic discharge (ESD) protecting element ESS, wherein the electrostatic discharge protecting element ESS may be disposed in the peripheral region PR, but not limited thereto. For example, the electrostatic discharge protecting element ESS may extend inward from the edge EG of the electronic device 100 to the bonding pad BP, but not limited thereto. The electrostatic discharge protecting element ESS may for example include a conductive layer SEL, wherein the bonding pad BP may be coupled to the conductive layer SEL. The conductive layer SEL may for example include semiconductor, but not limited thereto. According to the present embodiment, the electrostatic discharge protecting element ESS may be used to reduce static electricity accumulated on the bond pad BP and/or other electronic elements or reduce the amount of static electricity accumulated on the bond pad BP and/or other electronic elements. Therefore, the possibility of damage of electronic elements of the electronic device 100 due to electrostatic discharge may be reduced. It should be noted that although it is not shown in the figure, the electrostatic discharge protecting element ESS may be disposed in other regions of the electronic device 100, the present disclosure is not limited thereto.

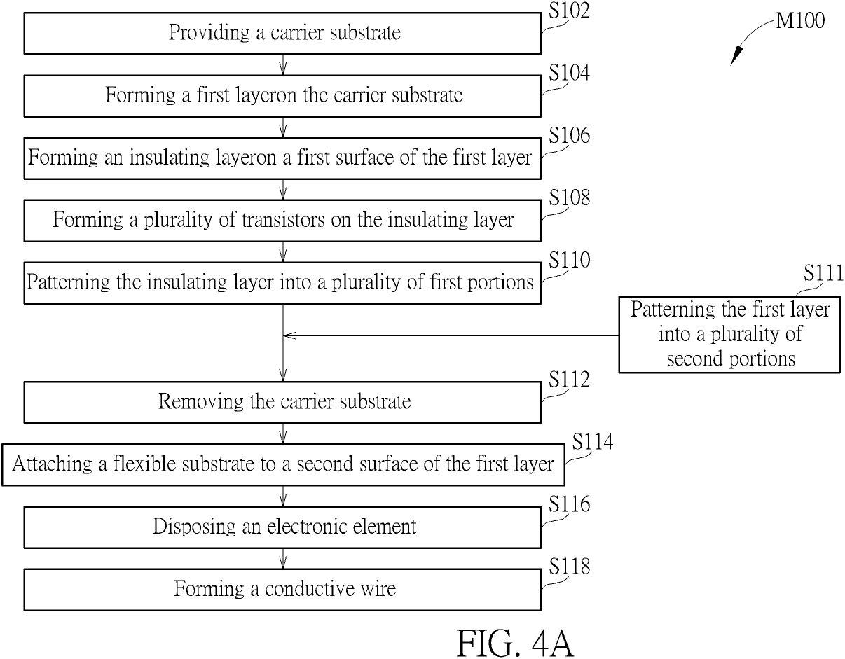

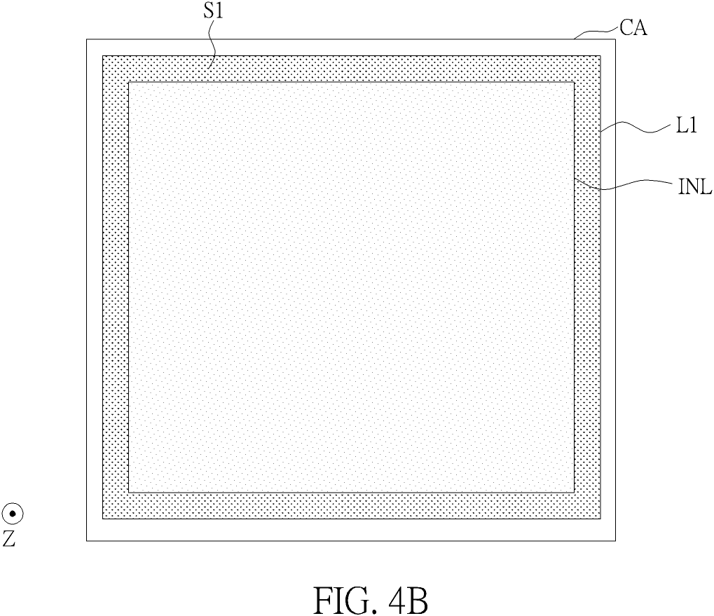

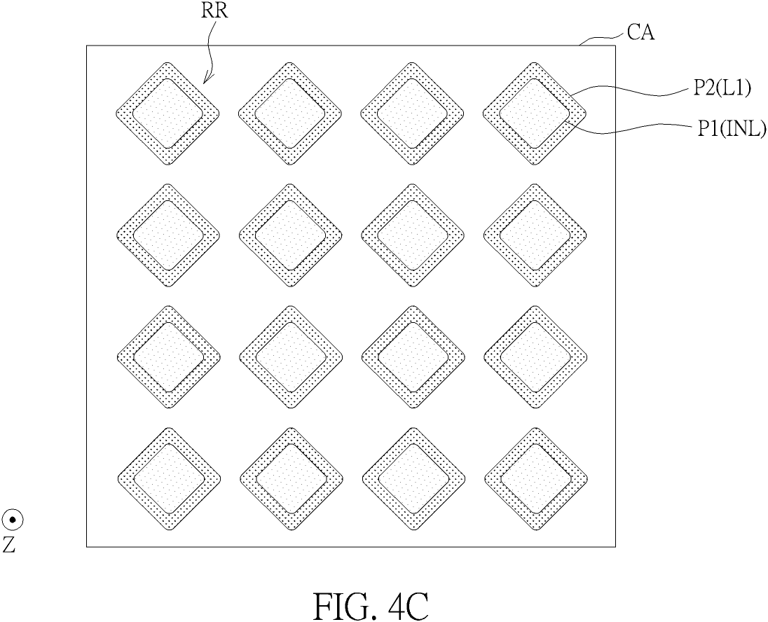

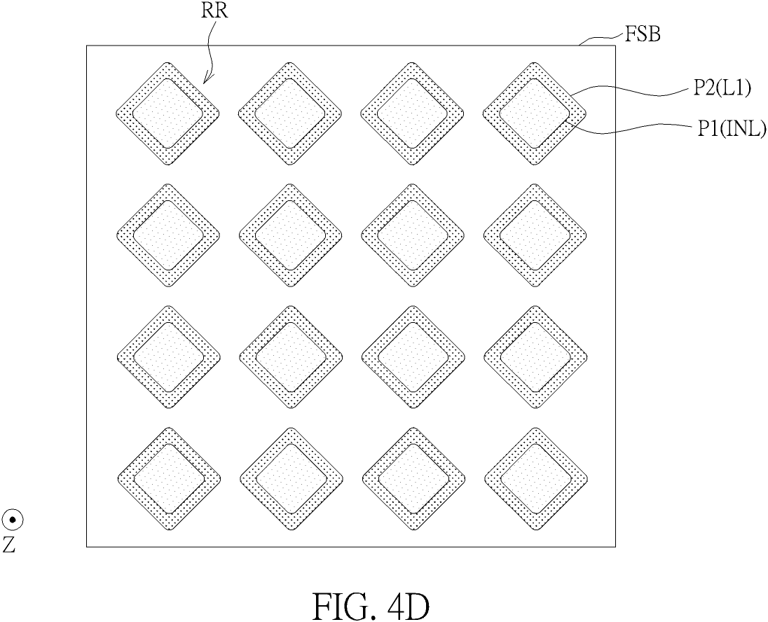

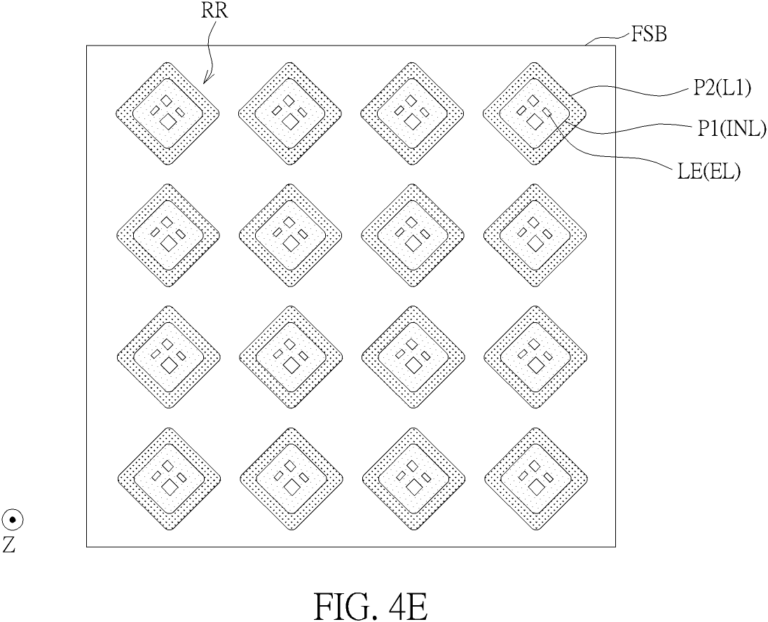

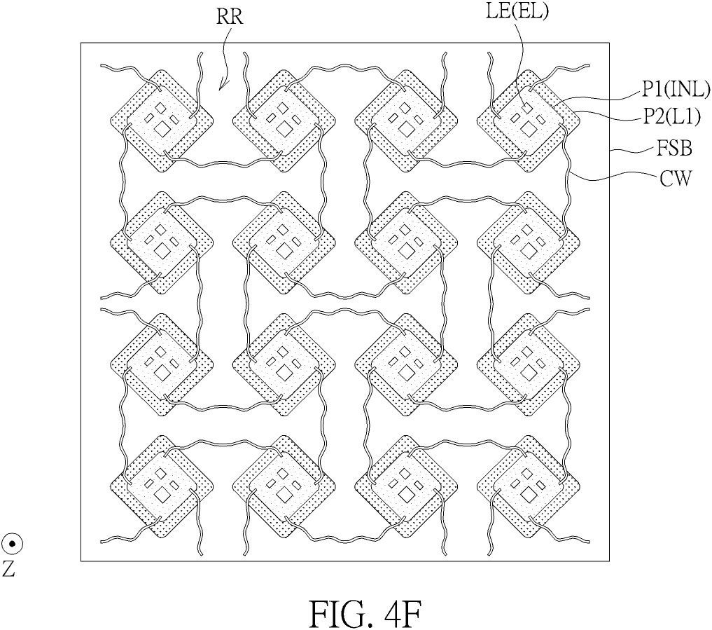

Referring to FIG. 4A to FIG. 4F and FIG. 5A to FIG. 5F, FIG. 4A shows a flow chart of a manufacturing process of the electronic device according to the second embodiment of the present disclosure, FIG. 4B, FIG. 4C, FIG. 4D, FIG. 4E and FIG. 4F schematically illustrate top views of the manufacturing process of the electronic device according to the second embodiment of the present disclosure, and FIG. 5A, FIG. 5B, FIG. 5C, FIG. 5D, FIG. 5E and FIG. 5F schematically illustrate cross-sectional views of the manufacturing process of the electronic device according to the second embodiment of the present disclosure. It should be noted that in order to simplify the figures, FIG. 4B to FIG. 4F do not show all of the elements and/or the layers, but the present embodiment is not limited thereto. According to the present embodiment, the manufacturing method M100 of the electronic device 200 may include the following steps:
S102: providing a carrier substrate
S104: forming a first layer on the carrier substrate
S106: forming an insulating layer on a first surface of the first layer
S108: forming a plurality of transistors on the insulating layer
S110: patterning the insulating layer into a plurality of first portions
S111: patterning the first layer into a plurality of second portions
S112: removing the carrier substrate
S114: attaching a flexible substrate to a second surface of the first layer
S116: arranging an electronic element
S118: forming a conductive wire

Each step in the manufacturing method M100 of the electronic device 200 will be detailed in the following.

In the manufacturing method M100 of the electronic device 200 of the present embodiment, the step S102 may be performed at first to provide a carrier substrate CA. The carrier substrate CA of the present disclosure may include rigid materials or flexible materials that can provide support, such as glass, metal plate (for example, stainless steel), non-metal plate (such as plastic), polyethylene terephthalate, other suitable materials or combinations of the above-mentioned materials, but not limited thereto.

Then, the step S104 may be performed to form the first layer L1 on the carrier substrate CA, and the step S106 may be performed to form the insulating layer INL on the first surface S1 of the first layer L1. As shown in FIG. 4B and FIG. 5A, the complete first layer L1 may be formed on the carrier substrate CA at first, and then the complete insulating layer INL may be formed on the first surface S1 of the first layer L1. The first surface S1 may be the surface of the first layer L1 away from the carrier substrate CA or the upper surface of the first layer L1. The materials of the first layer L1 and the insulating layer INL may refer to the above-mentioned contents, and will not be redundantly described.

After the insulating layer INL is formed on the first layer L1, the step S108 may be performed to form the plurality of transistors TS on the insulating layer INL. For example, as shown in FIG. 5A, the semiconductor SM, the insulating layer IL1 and the metal layer M1 may be formed on the insulating layer INL in sequence, and a doping process may be performed on the semiconductor SM, wherein the metal layer M1 may be patterned, a portion of the metal layer M1 may form the gate GE of the transistor TS, the semiconductor SM being doped may form the source region SR and the drain region DRR of the transistor TS, the channel region CR is included between the source region SR and the drain region DRR, and the insulating layer IL1 may form the gate insulating layer of the transistor TS, but not limited thereto. It should be noted that the transistors TS may have any suitable formation method according to the demands of the design of the product, and the present embodiment is not limited thereto.

After the transistors TS are disposed on the insulating layer INL, contact elements CT may be formed on the transistors TS. For example, as shown in FIG. 5A, the insulating layer IL2, the metal layer M2, the insulating layer IL3, the metal layer M3 and the insulating layer IL4 may be disposed on the metal layer M1 in sequence, wherein the metal layer M3 may be filled into the via V1 in the insulating layer IL3 and be coupled to the metal layer M2, and the metal layer M2 may be filled into the via V2 in the insulating layer IL2 and be coupled to the source region SR and/or the drain region DRR of the transistors TS, thereby forming the contact elements CT, but not limited thereto. The contact elements CT may be used to couple the transistors TS to the electronic elements EL (such as light emitting units LE) and/or the conductive wire CW disposed in the subsequent processes.

Then, the step S110 may be performed to pattern the insulating layer INL into the plurality of first portions P1. In the present embodiments, the step (step S110) of pattering the insulating layer INL may be performed after the step (step S108) of forming the plurality of transistors. Specifically, as shown in FIG. 4C and FIG. 5B, after the insulating layer IL4 is formed, the structure shown in FIG. 5A may be patterned to form at least one recess region RR. The recess region RR may be formed by removing a portion of the insulating layer IL4, a portion of the insulating layer IL3, a portion of the insulating layer IL2, a portion of the insulating layer IL1, a portion of the insulating layer INL and a portion of the first layer L1, but not limited thereto. In the present embodiment, the recess region RR may for example include the first areas OP1′ and the second areas OP, and the conductive wires CW formed in the subsequent process may be disposed in the first areas OP1′. That is, in the structure shown in FIG. 5A, the first areas OP1′ may correspond to the positions where the conductive wires CW are disposed, but not limited thereto. The insulating layer INL may be divided into the plurality of first portions P1 through the recess region RR (including the second area OP and the first area OP1′). According to the present embodiment, after the patterning process is performed on the insulating layer INL, the first portions P1 of the insulating layer INL are isolated from each other in the top view direction of the electronic device. For example, as shown in FIG. 4C, the insulating layer INL may be divided into the first portions P1 that are independently disposed and island-shaped, but not limited thereto. After the insulating layer INL is patterned into the plurality of first portions P1, at least one transistor TS may be disposed on each of the first portions P1. For example, as shown in FIG. 5B, the transistors TS may include at least one first transistor T1 and at least one second transistor T2 respectively disposed on two adjacent first portions P1, but not limited thereto.

In addition, the manufacturing method M100 of the present embodiment may further include the step S111: patterning the first layer L1 into the plurality of second portions P2. In detail, the first layer L1 may be patterned to form the plurality of second portions P2, and the plurality of second portions P2 are isolated from each other in the top view direction of the electronic device, as shown in FIG. 4C, but not limited thereto. According to the present embodiment, at least one first portion P1 may be disposed on a second portion P2, or at least one first portion P1 may correspond to a second portion P2. For example, as shown in FIG. 4C and FIG. 5B, a first portion P1 may be disposed on a second portion P2 and correspond to the second portion P2, but not limited thereto.

Furthermore, as shown in FIG. 4C and FIG. 5B, in addition to the patterning process of the insulating layer INL, the patterning process may further be performed on a portion of the insulating layer IL4 not corresponding to the recess region RR (or a portion of the insulating layer IL4 corresponding to the first portion P1), but not limited thereto. For example, a plurality of openings O2 may be formed in the portion of the insulating layer IL4 not corresponding to the recess region RR (or the portion of the insulating layer IL4 corresponding to the first portion P1), thereby patterning the portion of the insulating layer IL4 not corresponding to the recess region RR, but not limited thereto. The openings O2 may be used for arranging the electronic elements EL and/or the conductive wires CW in the subsequent processes. Accordingly, the patterned insulating layer IL4 may for example serve as the pixel defining layer (PDL), but not limited thereto.

After the insulating layer INL is patterned, the step S112 may be performed to remove the carrier substrate CA, and the step S114 may be performed to attach the flexible substrate FSB to the second surface S2 of the first layer L1. In other words, the insulating layer INL and the first layer L1 may be patterned at first, and then the carrier substrate CA is removed. Specifically, as shown in FIG. 5C, after the recess region RR and/or the openings O2 are formed, the structure shown in FIG. 5B may be inverted, such that the first layer L1 may be located above the insulating layer INL, and then the carrier substrate CA is removed. For example, before the structure shown in FIG. 5B is inverted, a sub carrier substrate (not shown) may be disposed on the surface of the structure away from the first layer L1 (such as the surface S3 of the insulating layer IL4, but not limited thereto) at first, and the structure may be inverted through the sub carrier substrate, but not limited thereto. The material of the sub carrier substrate may refer to the material of the carrier substrate CA, and will not be redundantly described. After the carrier substrate CA is removed, the attaching layer ATH may be disposed on the second surface S2 of the first layer L1, and the flexible substrate FSB may be attached to the second surface S2 of the first layer L1 through the attaching layer ATH. The second surface S2 of the first layer L1 may be opposite to the first surface S1 for disposing the insulating layer INL. In other words, the flexible substrate FSB and the insulating layer INL may respectively be disposed on two opposite surfaces of the first layer L1. Since the first layer L1 are divided into the second portions P2 disposed independently and being island-shaped, the attaching layer ATH may include the plurality of third portions P3. In another embodiment, the attaching layer ATH may be disposed on the flexible substrate FSB at first, and then the flexible substrate FSB may be attached to the second surface S2 of the first layer L1, and after the structure is inverted again, the attaching layer ATH may be patterned through the second areas OP and the first areas OP1′ to form the plurality of third portions P3 of the attaching layer ATH. Therefore, the plurality of third portions P3 may be disposed corresponding to the second portions P2, but not limited thereto. After the flexible substrate FSB is attached to the first layer L1, the structure may be inverted again (for example, inverted through the flexible substrate FSB), as shown in FIG. 4D and FIG. 5D.

After that, the step S116 may be performed to arrange the electronic elements EL. In the following, the light emitting unit LE is taken as an example of the electronic element EL for explanation, but the present embodiment is not limited thereto. Specifically, as shown in FIG. 4E and FIG. 5D, after the carrier substrate CA is removed and the flexible substrate FSB is attached to the first layer L1, the light emitting units LE may be disposed in the openings O2. The detailed structure of the light emitting unit LE may refer to the contents mentioned above, and will not be redundantly described. According to the present embodiment, the light emitting units LE may be disposed on the first portions P1 of the insulating layer INL and/or the second portions P2 of the first layer L1, or the light emitting units LE may be disposed corresponding to the first portions P1 and/or the second portions P2. In addition, one or more light emitting unit LE may be disposed on a first portion P1 and/or a second portion P2, the present embodiment is not limited thereto. After the light emitting units LE are disposed in the openings O2, the light emitting units LE may be coupled to the transistors TS through the bonding materials B1 and/or the bonding materials B2 and the contact elements CT, such that the light emitting units LE may be driven by the transistors TS to emit lights. It should be noted that the above-mentioned “arranging the electronic elements EL” may include the condition of transferring the electronic elements EL onto the first portions P1 and the condition of forming the electronic elements EL on the first portions P1. For example, the light emitting units LE shown in FIG. 5D may include in-organic light emitting diodes, and the light emitting units LE may be disposed in the openings O2 through transferring, but not limited thereto. In some other embodiments (not shown), the light emitting units LE (for example, the light emitting unit LE may be an organic light emitting diode which includes a light emitting layer and electrode layers formed in sequence) may be formed in the openings O2 and coupled to the transistors TS, such that the light emitting units LE may be driven by the transistors TS to emit lights. Therefore, the light emitting units LE may be disposed on the first portions P1 of the insulating layer INL and/or the second portions P2 of the first layer L1.

After the electronic elements EL are arranged, the step S118 may be performed to form the conductive wire CW. According to the present embodiment, a portion of the conductive wire CW may be disposed on the upper surfaces of the insulating layers IL4 (that is, the surface S3) respectively on two adjacent first portions P1, and another portion of the conductive wire CW may extend into the first area OP1′ of the recess region RR. Specifically, as shown in FIG. 4F and FIG. 5E, the conductive wire CW may be disposed on the surfaces S3 of the insulating layers IL4 respectively on two adjacent first portions P1 and the sidewall SW and the bottom surface BS of the first area OP1′, such that the conductive wire CW may extend from a first portion P1 (or second portion P2) to another first portion P1 (or second portion P2) in the top view direction of the electronic device 200, but not limited thereto. Since the first area OP1′ may expose the flexible substrate FSB, at least a portion of the conductive wire CW may contact the flexible substrate FSB. In addition, the portion of the conductive wire CW disposed on the insulating layer IL4 may penetrate through the insulating layer IL4 and be coupled to the contact elements CT, and the conductive wire CW may be coupled to the transistors TS (such as the first transistor T1 and the second transistor T2) respectively on two adjacent first portions P1 through the content elements CT. Accordingly, the first transistor T1 and the second transistor T2 respectively on two adjacent first portions P1 may be coupled to each other through the conductive wire CW. In the present embodiment, the electronic elements EL (the light emitting units LE) may be coupled to the transistors TS that are coupled to the conductive wires CW. For example, the light emitting unit LE in the left part of FIG. 5E may be coupled to the first transistor T1 that is coupled to the conductive wire CW, but not limited thereto. In some embodiments, multiple first transistors T1 (or second transistors T2) may be disposed on a first portion P1, and the light emitting unit LE and the conductive wire CW may be coupled to different first transistors T1 (or second transistors T2). In such situation, since the transistors TS on the same first portion P1 may be coupled to each other, the light emitting unit LE may still be coupled to the transistor TS that is coupled to the conductive wire CW.

As shown in FIG. 5F, after the conductive wire CW is disposed, an insulating layer INL2 may further be disposed to form the electronic device 200 of the present embodiment. The insulating layer INL2 may contact the flexible substrate FSB and encapsulate the layers and the electronic elements (such as electronic elements EL, conductive wire CW, and the like) between the insulating layer INL2 and the flexible substrate FSB, and the insulating layer INL2 may be filled into the second areas OP and the first areas OP1′ to provide protection.

It should be noted that the manufacturing method M100 of the electronic device 200 in the present embodiment is not limited to the above-mentioned steps or processes. Other steps may be inserted between the steps in the manufacturing method M100 according to the demands. In addition, any step in the manufacturing method M100 may be adjusted in order or deleted according to the demands. In some embodiments, after the flexible substrate FSB is attached to the first layer L1, the conductive wire CW may be disposed at first (the step S118), and then the electronic elements EL are arranged (the step S116). In other words, the order of the step S116 and the step S118 may be changed. In some embodiments, after the insulating layer INL is patterned into the plurality of first portions P1 (the step S110) and the first layer L1 is patterned into the plurality of second portions P2 (the step S111), a sacrificing layer (not shown) may be formed on the stacked structure shown in FIG. 5B, wherein the sacrificing layer may at least cover the upper surface (surface S3) of the insulating layer IL4 and for example be filled into the openings O2 of the patterned insulating layer IL4. The sacrificing layer may be used to reduce the possibility of damage to the surface S3 of the insulating layer IL4 when the stacked structure shown in FIG. 5B is being inverted. In other words, it is not necessary to dispose the sub carrier substrate on the surface S3 of the insulating layer IL4, but not limited thereto. In some embodiments, the sacrificing layer may include multiple portions disposed respectively corresponding to the first portions P1 (or the second portions P2). That is, the sacrificing layer may be patterned. In some embodiments, a complete sacrificing layer may be disposed on the formed stacked structure, wherein the sacrificing layer may be filled into the recess region RR. Therefore, the possibility of mistakes and/or damage to the surface S3 of the insulating layer IL4 during the inverting process of the stacked structure may be reduced, thereby achieving the effect of improving the process. After the stacked structure shown in FIG. 5B is inverted, the carrier substrate CA may be removed, and the flexible substrate FSB may be attached to the first layer L1. After that, the stacked structure may be inverted again, and the sacrificing layer may be removed before arranging the electronic elements EL and/or disposing the conductive wires CW, but not limited thereto.

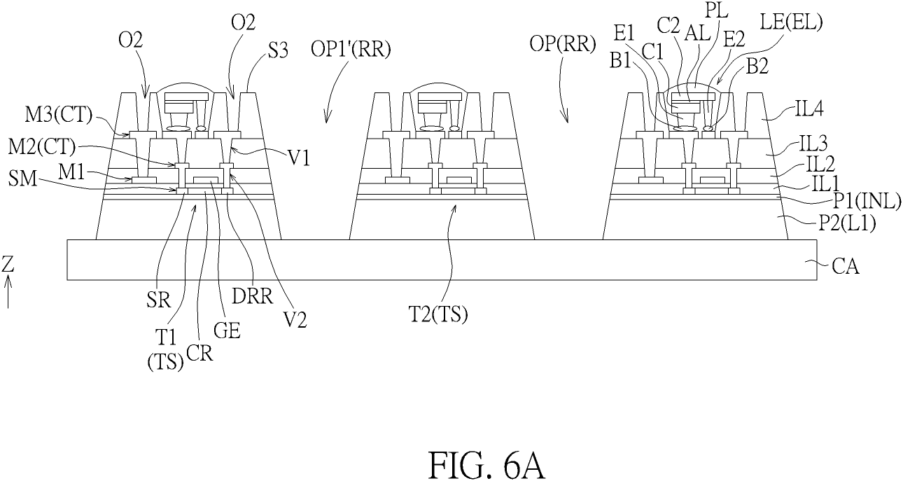

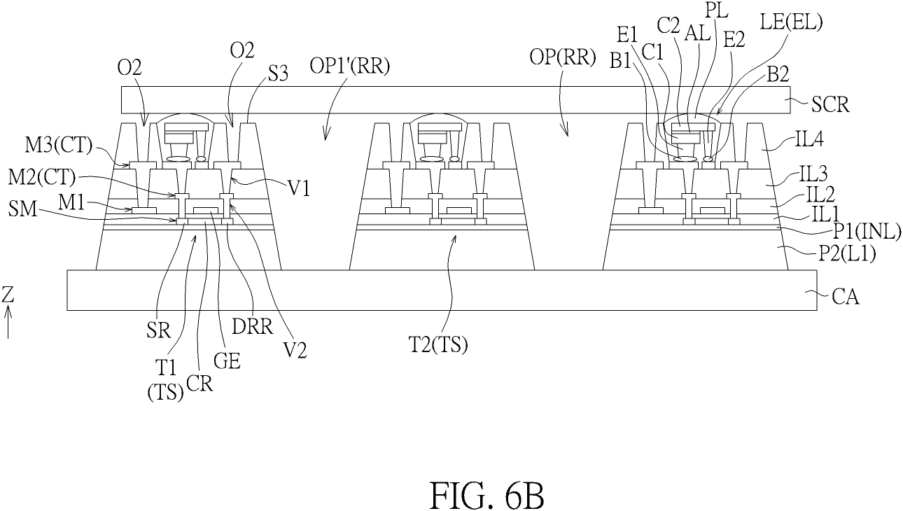

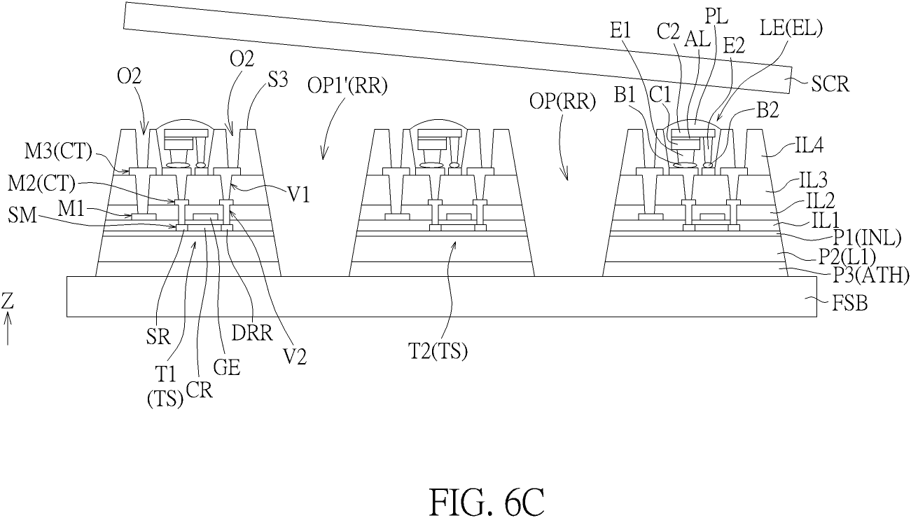

Referring to FIG. 6A to FIG. 6C, FIG. 6A, FIG. 6B and FIG. 6C schematically illustrate cross-sectional views of a manufacturing process of an electronic device according to a variant embodiment of the second embodiment of the present disclosure. One of the main differences between the manufacturing method of the present variant embodiment and the manufacturing method of the second embodiment shown in FIG. 5A to FIG. 5F is that the electronic elements EL are arranged (the step S116) at first, and then the flexible substrate FSB is attached to the first layer L1 (the step S114) in the manufacturing method of the electronic device of the present variant embodiment. In detail, according to the present variant embodiment, after the insulating layer INL is patterned into the plurality of first portions P1 (the step S110), the first layer L1 is patterned into the plurality of second portions P2 (the step S111) and/or a portion of the insulating layer IL4 not corresponding to the recess region RR is patterned to form the openings O2 (as shown in FIG. 5B), the electronic elements EL may be arranged in the openings O2 (the step S118) at first to form the stacked structure shown in FIG. 6A. After that, as shown in FIG. 6B, a sub carrier substrate SCR may be disposed on the surface of the structure shown in FIG. 6A away from the first layer L1 (for example, the surface S3 of the insulating layer IL4, but not limited thereto), and the stacked structure shown in FIG. 6B may be inverted through the sub carrier substrate SCR. The sub carrier substrate SCR may cover the surface S3 of the insulating layer IL4, the electronic elements EL and/or the protecting layer PL covering the electronic elements EL, but not limited thereto. After the structure shown in FIG. 6B is inverted, the carrier substrate CA may be removed, and the flexible substrate FSB may be attached to the first layer L1. After that, the structure including the flexible substrate FSB may be inverted, and the sub carrier substrate SCR may be removed, as shown in FIG. 6C, but not limited thereto. After the sub carrier substrate SCR is removed, the steps of disposing the conductive wire CW (the step S118), disposing the insulating layer INL2, and the like may be performed, wherein the details of the steps may refer to the contents mentioned above, and will not be redundantly described.

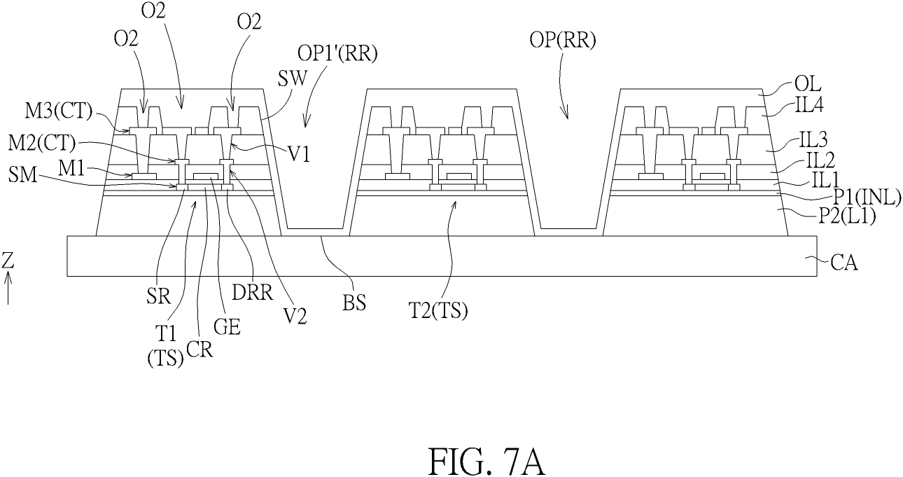

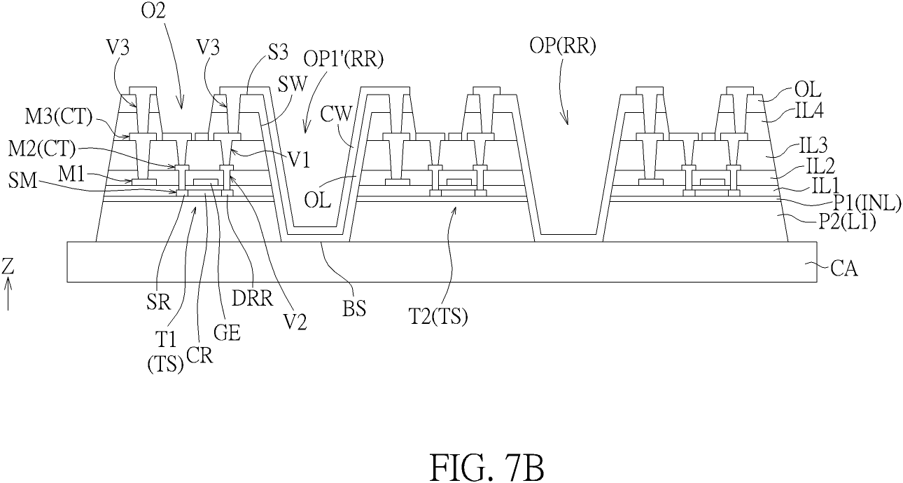

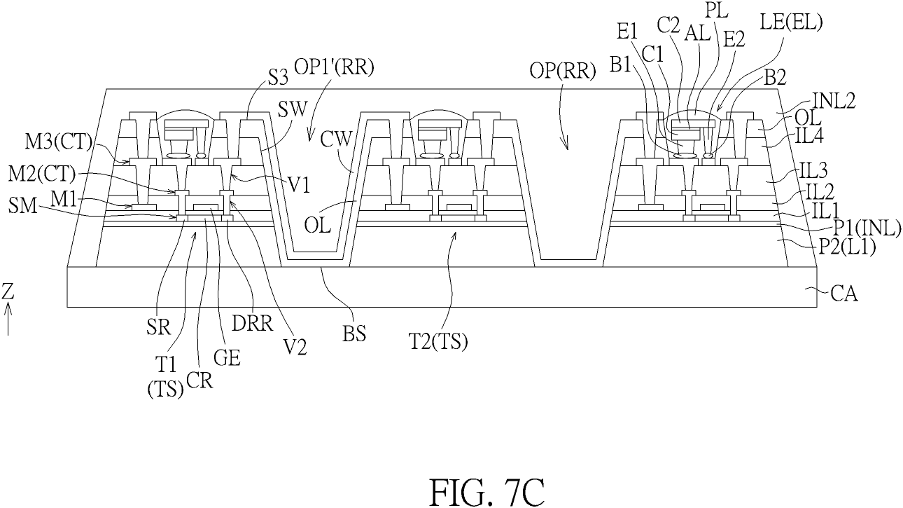

Referring to FIG. 7A to FIG. 7C, FIG. 7A, FIG. 7B and FIG. 7C schematically illustrate cross-sectional views of a manufacturing process of an electronic device according to another variant embodiment of the second embodiment of the present disclosure. According to the present variant embodiment, after the insulating layer INL is patterned into the plurality of first portions P1 (the step S110), the first layer L1 is patterned into the plurality of second portions P2 (the step S111) and/or a portion of the insulating layer IL4 not corresponding to the recess region RR is patterned to form the openings O2 (as shown in FIG. 5B), an organic layer OL may be disposed on the surface (such as the surface S3 of the insulating layer IL4) of the structure shown in FIG. 5B at first, wherein the organic layer OL may be filled into the openings O2 and extend along the sidewall SW and the bottom surface BS of the first area OP1′ and the sidewall and the bottom surface of the second area OP. In other words, the organic layer OL may be disposed on the upper surface of the structure shown in FIG. 5B, but not limited thereto. The organic layer OL may include any suitable organic insulating material, such as acrylic resin, epoxy resin, siloxane, silicone, other suitable materials or combinations of the above-mentioned materials. After the organic layer OL is formed, as shown in FIG. 7B, a portion of the organic layer OL may be removed to expose the contact elements CT coupled to the conductive wires CW and/or the electronic elements EL. For example, the portion of the organic layer OL corresponding to the openings O2 may be removed to form a plurality of vias (such as the vias V3) exposing the contact elements CT, but not limited thereto. Viewing in the direction Z, the vias V3 and the openings O2 may at least partially overlap each other to expose the contact elements CT. After that, the step of disposing the conductive wire CW (the step S118) may be performed, wherein the conductive wire CW may be disposed on the organic layer OL. In addition, the conductive wire CW may be filled into the vias (such as the vias V3) in the organic layer OL and be coupled to the contact elements CT through the vias V3 in the organic layer OL, thereby being coupled to the transistors TS. After the conductive wire CW is disposed on the organic layer OL, as shown in FIG. 7C, the electronic elements EL and the insulating layer INL2 may be formed. After that, the carrier substrate CA may be removed, and the flexible substrate FSB may be attached to the first layer L1, thereby forming the electronic device 200. In other words, in the present variant embodiment, the manufacturing method M100 may further include the step of disposing the organic layer OL before the step of arranging the electronic elements EL (the step S116) and the step of forming the conductive wire CW (the step S118), but not limited thereto. Since the organic layer OL may be disposed before the conductive wire CW is disposed, the conductive wire CW may not contact the flexible substrate FSB. Specifically, the organic layer OL may be disposed between the conductive wire CW and the flexible substrate FSB.

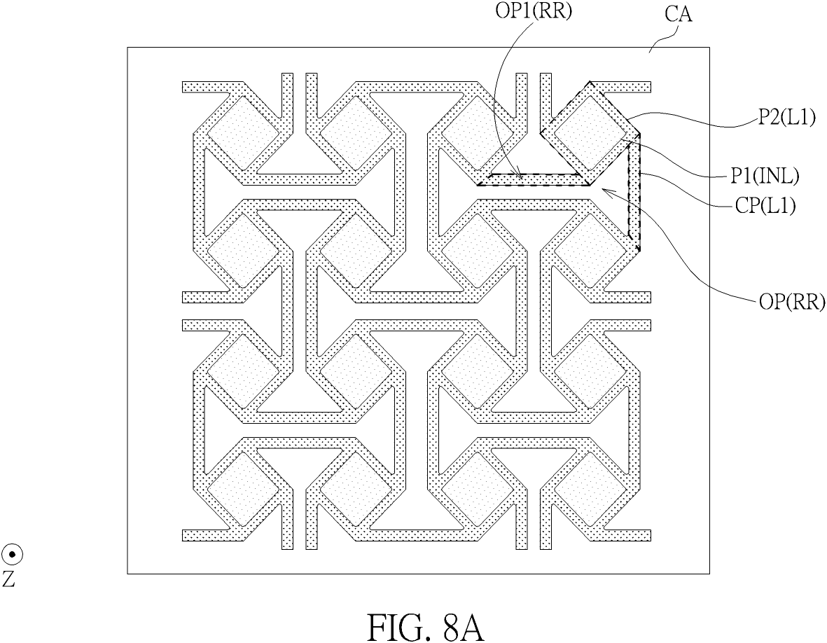

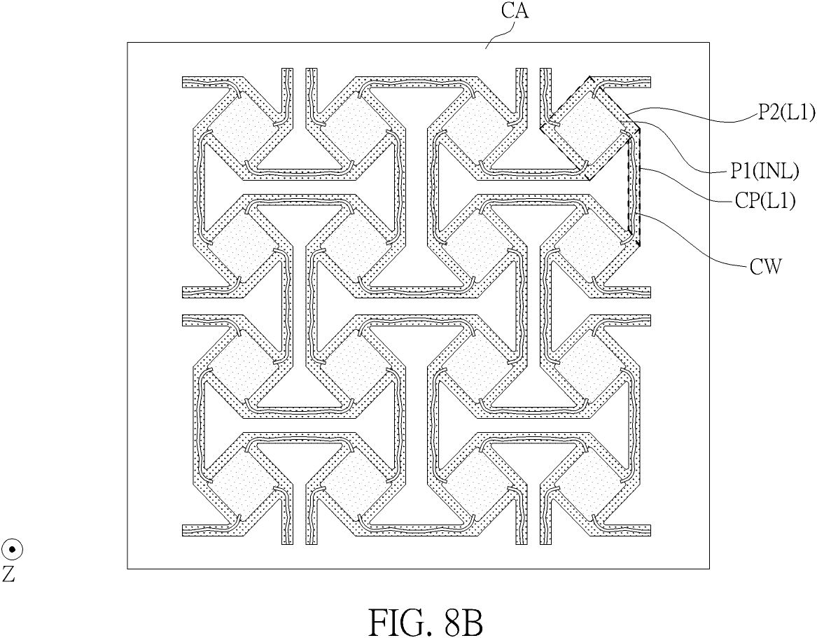

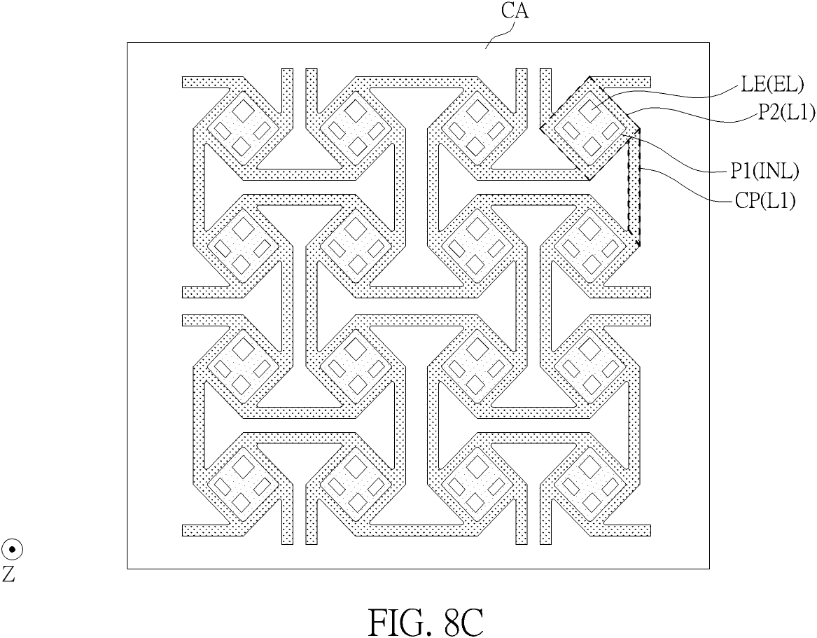

Referring to FIG. 8A to FIG. 8C and FIG. 9A to FIG. 9D, FIG. 8A, FIG. 8B and FIG. 8C schematically illustrate top views of the manufacturing process of the electronic device according to the first embodiment of the present disclosure, and FIG. 9A, FIG. 9B, FIG. 9C and FIG. 9D schematically illustrate cross-sectional views of the manufacturing process of the electronic device according to the first embodiment of the present disclosure. The manufacturing method of the electronic device 100 of the present embodiment may refer to the manufacturing method M100 shown in FIG. 4A. In detail, the manufacturing method of the electronic device 100 may first include:
S102: providing a carrier substrate
S104: forming a first layer on the carrier substrate
S106: forming an insulating layer on a first surface of the first layer
S108: forming a plurality of transistors on the insulating layer

The details about the steps S102 to S108 may refer to the contents mentioned above, and will not be redundantly described. After performing the above-mentioned steps, the structure formed may for example refer to the stacked structure shown in FIG. 5A, but not limited thereto.

After that, the step S110 may be performed to pattern the insulating layer INL into the plurality of first portions P1, and the step S111 may be performed to pattern the first layer L1 into the plurality of second portions P2. According to the present embodiment, the plurality of connecting portions CP may be formed when patterning the first layer L1, wherein a connecting portion CP may connect two adjacent second portions P2. In other words, after the first layer L1 of the present embodiment is patterned, the plurality of second portions P2 and the connecting portions CP connected between adjacent second portions P2 may be formed, but not limited thereto. In detail, as shown in FIG. 8A and FIG. 9A, the structure shown in FIG. 5A may be patterned to form at least one recess region RR. In the present embodiment, the recess region RR may for example include the second areas OP and the first areas OP1, wherein the second areas OP may expose the flexible substrate FSB of the electronic device 100, and the first areas OP1 may expose the connecting portions CP of the first layer L1 of the electronic device 100. In other words, the depth of the second area OP and the depth of the first area OP1 may be different. Accordingly, the first areas OP1 may correspond to the connecting portions CP of the first layer L1. FIG. 8A exemplarily show the positions of the second areas OP and the first areas OP1. In addition, in the present embodiment, the second areas OP and the first areas OP1 may be located at any suitable position, such that the first portions P1 of the insulating layer INL are isolated from each other in the top view direction (the direction Z) of the electronic device 100. Furthermore, in addition to forming the second areas OP and/or the first areas OP in the structure shown in FIG. 5A, a portion of the insulating layer IL4 not corresponding to the recess region RR may be patterned to form the openings O2, but not limited thereto.

After the insulating layer INL and the first layer L1 are patterned, the step S118 may for example be performed to form the conductive wire CW, but not limited thereto. In other words, the step of forming the conductive wire CW may be performed after the step of patterning the first layer L1. For example, as shown in FIG. 8B, the conductive wires CW may be disposed on the connecting portions CP and extend on the connecting portions CP. In addition, as shown in FIG. 9B, the conductive wire CW may extend into the first area(s) OP1. Specifically, at least a portion of the conductive wire CW may be disposed on the sidewall SW and the bottom surface BS of the first area OP1 or extend along the sidewall SW and the bottom surface BS of the first area OP1, such that the conductive wire CW may extend on the connecting portion CP. In addition, the conductive wire CW may be coupled to the transistors TS respectively on two adjacent first portions P1, such that these transistors TS may be coupled to each other through the conductive wire CW. For example, a portion of the conductive wire CW may extend on the upper surface of the insulating layer IL4, the portion of the conductive wire CW may penetrate through the insulating layer IL4 and be coupled to the contact elements CT, and the portion of the conductive wire CW may be coupled to the first transistor T1 and the second transistor T2 respectively on two adjacent first portions P1 through the contact elements CT, but not limited thereto. After the conductive wire CW is formed, the step of arranging the electronic elements EL (the step S116) may be formed at first to form the structure shown in FIG. 9B.

Or, in some embodiments, after the insulating layer INL and the first layer L1 are patterned, the step S116 may be performed to arrange the electronic elements EL. For example, as shown in FIG. 8C, the electronic elements EL (the light emitting units LE) may be arranged on the first portions P1 (or the second portions P2) or arranged corresponding to the first portions P1 (or the second portions P2). In addition, as shown in FIG. 9B, the electronic elements EL may be arranged in the openings O2 in the patterned insulating layer IL4. After the electronic elements EL are arranged, the step of forming the conductive wire CW (the step S118) may be performed to form the structure shown in FIG. 9B.

As shown in FIG. 9C, after the electronic elements EL are arranged and the conductive wire CW is disposed, the insulating layer INL2 may be formed. The insulating layer INL2 may contact the flexible substrate FSB and encapsulate the layers and the electronic elements (such as electronic elements EL, conductive wire CW, and the like) between the insulating layer INL2 and the flexible substrate FSB. The insulating layer INL2 may be filled into the second areas OP and the first areas OP1 to provide protection.

As shown in FIG. 9D, after the insulating layer INL2 is formed, the step S112 may be performed to remove the carrier substrate CA, and the step S114 may be performed to attach the flexible substrate FSB to the second surface S2 of the first layer L1, thereby forming the electronic device 100. Accordingly, in the manufacturing method of the electronic device 100 of the present embodiment, the electronic elements EL and/or the conductive wires CW may be arranged or disposed at first, and then the carrier substrate CA is removed, and the flexible substrate FSB is attached to the first layer L1, but not limited thereto.

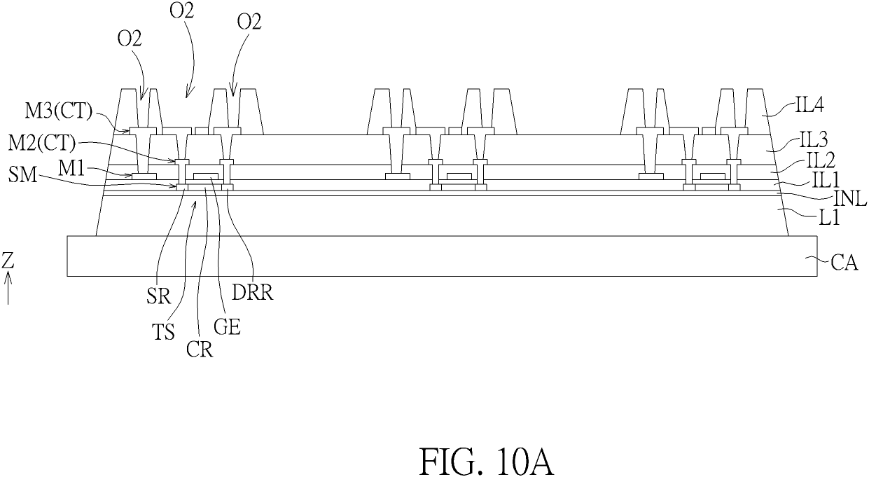

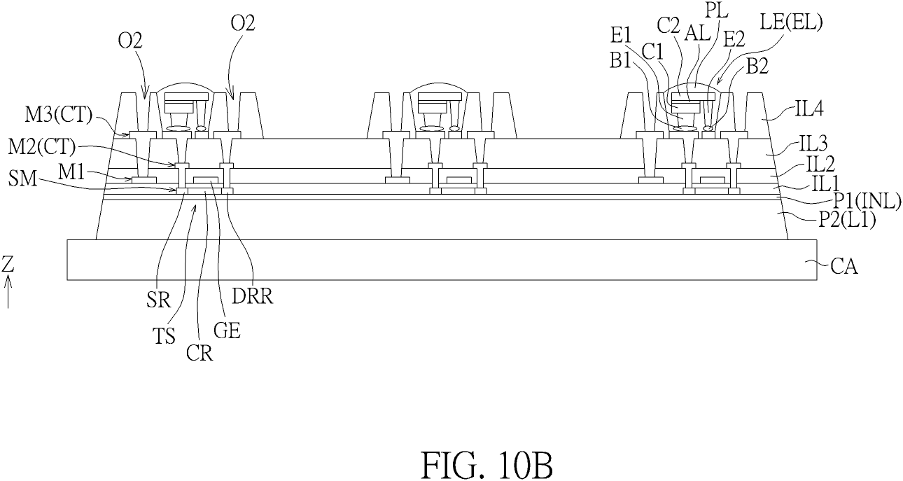

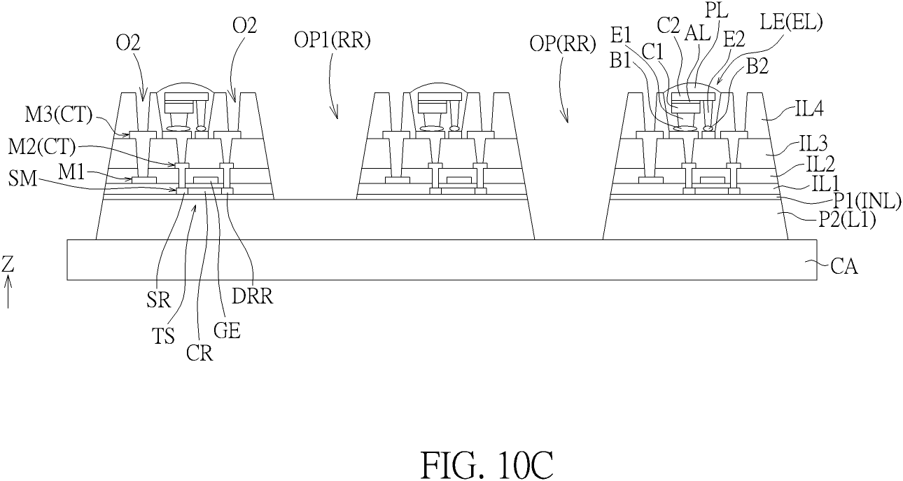

Referring to FIG. 10A to FIG. 10C, FIG. 10A, FIG. 10B and FIG. 10C schematically illustrate cross-sectional views of a manufacturing process of an electronic device according to a variant embodiment of the first embodiment of the present disclosure. According to the present variant embodiment, as shown in FIG. 10A, after the steps of forming the first layer L1 on the carrier substrate CA (the step S104), forming the insulating layer INL on the first layer L1 (the step S106) and forming the transistors TS on the insulating layer INL (the step S108), the insulating layer IL4 may be patterned at first to form the plurality of openings O2 in the insulating layer IL4. After that, as shown in FIG. 10B, the step S116 may be performed to arrange the electronic elements EL. Specifically, the electronic elements EL (such as the light emitting units LE) may be arranged in the openings O2, wherein the electronic elements EL may be coupled to the transistors TS through the contact elements CT. After the electronic elements EL are arranged, as shown in FIG. 10C, the step S110 may be performed to pattern the insulating layer INL into the plurality of first portions P1, and the step S111 may be performed to pattern the first layer L1 into the plurality of second portions P2. The details of the step S110 and the step S111 may refer to the contents mentioned above, and will not be redundantly described. After the first layer L1 and the insulating layer INL are patterned, the steps such as forming the conductive wire CW (the step S118), forming the insulating layer INL2, removing the carrier substrate CA (the step S112) and attaching the flexible substrate FSB to the first layer L1 (the step S114) may for example be performed in sequence to form the electronic device 100. Accordingly, in the manufacturing method of the electronic device 100 of the present variant embodiment, the electronic elements EL may be arranged at first, and then the first layer L1 and the insulating layer INL may be patterned, but not limited thereto.

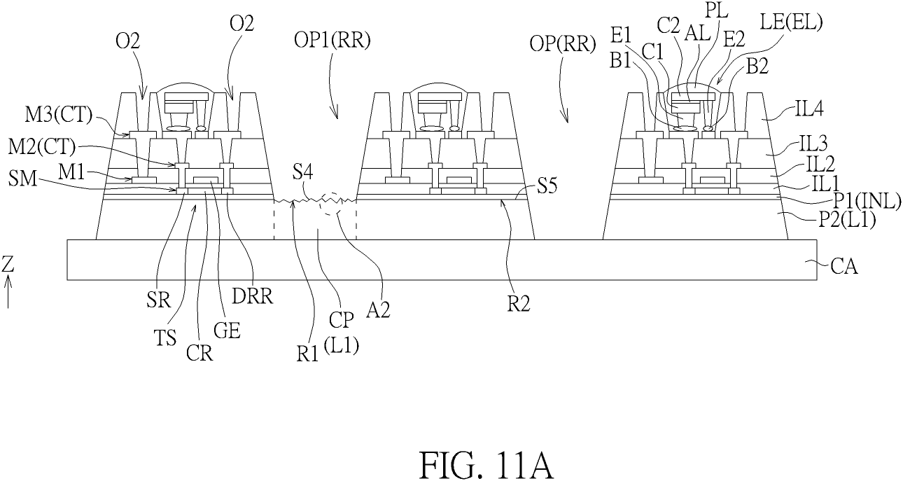

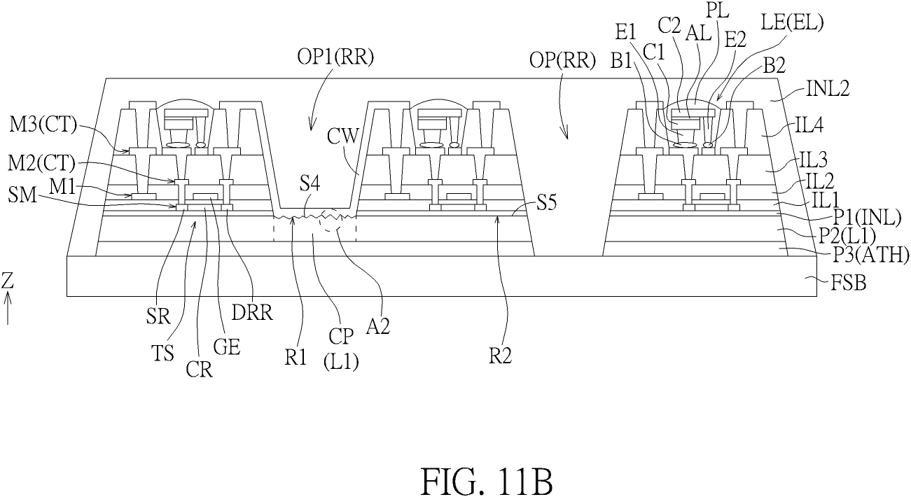

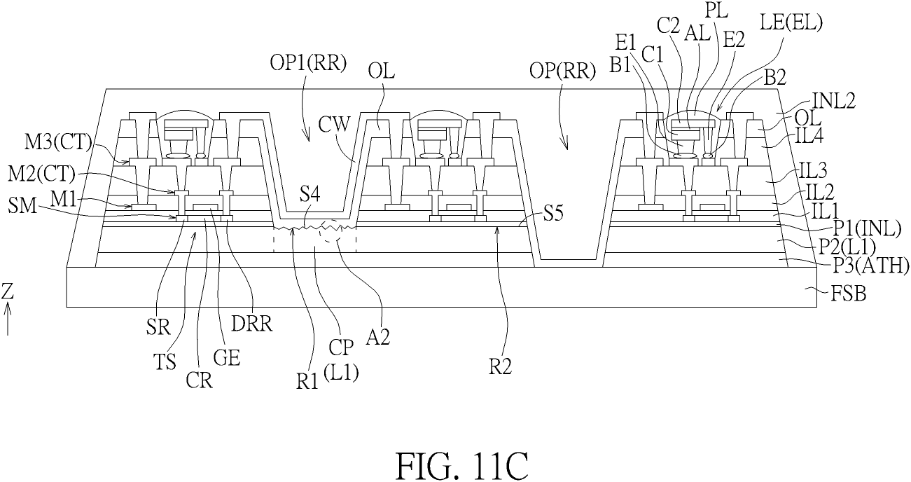

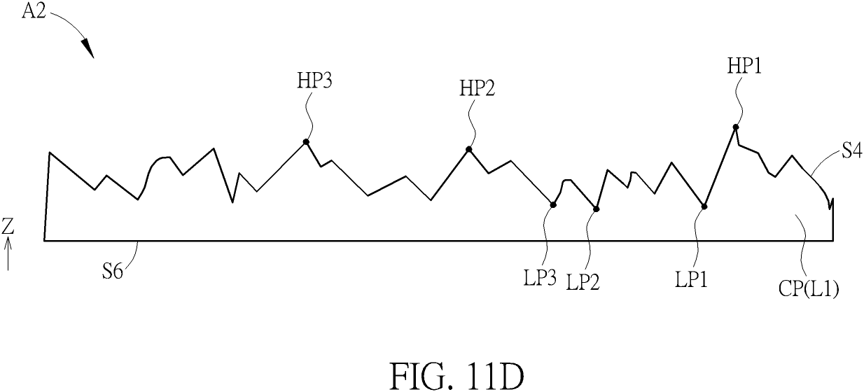

Referring to FIG. 11A to FIG. 11C, FIG. 11A and FIG. 11B schematically illustrate cross-sectional views of a manufacturing process of an electronic device according to another variant embodiment of the first embodiment of the present disclosure, and FIG. 11C schematically illustrates a cross-sectional view of an electronic device according to yet another variant embodiment of the first embodiment of the present disclosure. According to the present variant embodiment, after the first layer L1 is patterned to form the second portions P2 and the connecting portions CP, the roughness of the upper surface of the second portion P2 and the roughness of the upper surface of the connecting portion CP may be different. Specifically, as shown in FIG. 11A, the upper surface (that is, the surface S4) of the connecting portion CP may have a roughness R1, and the upper surface (that is, the surface S5) of the second portion P2 may have a roughness R2, wherein the roughness R1 and the roughness R2 may be different. According to the present variant embodiment, the roughness R1 may be greater than the roughness R2, and a ratio of the roughness R2 to the roughness R1 may be greater than or equal to 0.3 and lower than 1 (that is, 0.3≤R2/R1<1), but not limited thereto. In some embodiments, the ratio of the roughness R2 to the roughness R1 may be greater than or equal to 0.5 and lower than 0.9 (that is, 0.5≤R2/R1<0.9). As shown in FIG. 11B, since the roughness of the upper surface of the connecting portion CP may be greater than the roughness of the upper surface of the second portion P2, the adhesion between the conductive wire CW disposed on the connecting portion CP and the connecting portion CP may be improved, thereby improving the yield of the electronic device 100. Or, in some embodiments, as shown in FIG. 11C, the electronic device 100 may further include the organic layer OL disposed between the conductive wire CW and the connecting portion CP, wherein the material of the organic layer OL may refer to the contents mentioned above, and will not be redundantly described. Since the organic layer OL may be disposed on the connecting portion CP, the adhesion between the organic layer OL and the connecting portion CP may be improved by making the roughness of the upper surface of the connecting portion CP greater.

Referring to FIG. 11D, FIG. 11D schematically illustrates a method for measuring a roughness of a first layer. Specifically, FIG. 11D shows a partial enlarged view of the portion A2 shown in FIG. 11A. According to the present variant embodiment, in order to measure the roughness of a surface, a region may be chosen in the cross-sectional view of the surface, and at least one high point and at least one low point of the surface may be selected in the region, wherein the roughness of the surface may for example be defined as the average of the height differences between the selected high point(s) and low point(s), but not limited thereto. The cross-sectional view of the surface may for example be obtained through the scanning electron microscope (SEM), but not limited thereto. In addition, the high point and the low point may for example be the highest point and the lowest point of the surface in the region respectively, but not limited thereto. In the following, the surface S4 of the connecting portion CP is taken as an example to describe the definition of the roughness. As shown in FIG. 11D, in the portion A2, the surface S4 of the connecting portion CP may include three high points (the point HP1, the point HP2 and the point HP3) and three low points (the point LP1, the point LP2 and the point LP3), wherein the point HP1, the point HP2 and the point HP3 may be the three highest points of the surface S4 in the portion A2, and the point LP1, the point LP2 and the point LP3 may be the three lowest points of the surface S4 in the portion A2. After the high point(s) and the low point(s) are found, three height differences respectively between the three high points and the three low points in the direction Z may be measured, and the roughness R1 of the surface S4 of the connecting portion CP may for example be defined as the average of the three height differences, but not limited thereto. For example, the heights respectively from the point HP1, the point HP2, the point HP3, the point LP1, the point LP2 and the point LP3 to the bottom surface S6 of the connecting portion CP in the direction Z may be measured, and the roughness of the surface S4 may be obtained by calculating the average value after subtracting the sum of the heights of the three low points from the sum of the heights of the three high points. It should be noted that the definition of the roughness of the surface of the present variant embodiment is not limited to the above-mentioned contents. In some embodiments, more or less high points and low points of the surface S4 may be selected, thereby defining the roughness of the surface S4.

In summary, a flexible electronic device and a manufacturing method thereof is provided by the present disclosure, wherein the inorganic insulating layer may not be disposed on the connecting portions of the substrate of the flexible electronic device. Accordingly, when the flexible electronic device is deformed (such as being stretched), the stress on the connecting portion may be reduced, thereby reducing the possibility of breakage of the connecting portions and the conductive wire. In another aspect, when the substrate of the flexible electronic device does not include the connecting portion, the inorganic insulating layer may not be disposed corresponding to the conductive wire, such that the stress on the conductive wire may be reduced when the flexible electronic device is deformed. Therefore, the stretchability or the reliability of the flexible electronic device may be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method for manufacturing a flexible electronic device, the method comprising:
providing a carrier substrate;
forming a first layer on the carrier substrate;
forming an insulating layer on a first surface of the first layer;
forming a plurality of transistors on the insulating layer, wherein the plurality of transistors comprise at least one first transistor and at least one second transistor;
patterning the insulating layer into a plurality of first portions, wherein the at least one first transistor and the at least one second transistor are respectively disposed on two adjacent ones of the plurality of first portions;
removing the carrier substrate; and
attaching a flexible substrate to a second surface of the first layer opposite to the first surface;
wherein the two adjacent ones of the plurality of first portions are isolated from each other.

2. The method as claimed in claim 1, wherein the insulating layer is patterned after forming the plurality of transistors.

3. The method as claimed in claim 1, further comprising:
patterning the first layer into a plurality of second portions before removing the carrier substrate, wherein at least one of the plurality of first portions is disposed on one of the plurality of second portions.

4. The method as claimed in claim 3, wherein two adjacent ones of the plurality of second portions are isolated from each other.

5. The method as claimed in claim 4, further comprising:
forming a conductive wire coupled to the at least one first transistor and the at least one second transistor, wherein the conductive wire contacts the flexible substrate.

6. The method as claimed in claim 3, further comprising:
patterning the first layer into a plurality of connecting portions, wherein at least one of the plurality of connecting portions connects two adjacent ones of the plurality of second portions.

7. The method as claimed in claim 6, further comprising:
forming a conductive wire coupled to the at least one first transistor and the at least one second transistor, wherein the conductive wire contacts the at least one of the plurality of connecting portions.

8. The method as claimed in claim 7, wherein the conductive wire is formed after patterning the first layer.

9. The method as claimed in claim 1, further comprising:
arranging an electronic element on one of the two adjacent ones of the plurality of first portions, wherein the electronic element couples to the at least one first transistor or the at least one second transistor.

10. A flexible electronic device, comprising:
a flexible substrate;
an insulating layer disposed on the flexible substrate and comprising a plurality of first portions; and
a plurality of transistors disposed on the insulating layer and comprising at least one first transistor and at least one second transistor, wherein the at least one first transistor and the at least one second transistor are respectively disposed on two adjacent ones of the plurality of first portions;
wherein the two adjacent ones of the plurality of first portions are isolated from each other.

11. The flexible electronic device as claimed in claim 10, further comprising a first layer disposed between the insulating layer and the flexible substrate, wherein the first layer comprises a plurality of second portions and at least one of the plurality of first portions is disposed on one of the plurality of second portions.

12. The flexible electronic device as claimed in claim 11, wherein two adjacent ones of the plurality of second portions are isolated from each other.

13. The flexible electronic device as claimed in claim 12, further comprising a conductive wire coupled to the at least one first transistor and the at least one second transistor, wherein the conductive wire contacts the flexible substrate.

14. The flexible electronic device as claimed in claim 11, wherein the first layer further comprises a plurality of connecting portions, and at least one of the plurality of connecting portions connects two adjacent ones of the plurality of second portions.

15. The flexible electronic device as claimed in claim 14, further comprising a conductive wire coupled to the at least one first transistor and the at least one second transistor, wherein the conductive wire contacts the at least one of the plurality of connecting portions.

16. The flexible electronic device as claimed in claim 15, wherein the flexible substrate comprises an opening overlapped with the conductive wire.

17. The flexible electronic device as claimed in claim 11, further comprising an adhesive layer disposed between the first layer and the flexible substrate.

18. The flexible electronic device as claimed in claim 17, wherein the adhesive layer comprises a plurality of third portions disposed under the plurality of second portions.

19. The flexible electronic device as claimed in claim 10, further comprising an electronic element disposed on one of the two adjacent ones of the plurality of first portions and coupled to the at least one first transistor or the at least one second transistor.
